(19) United States
(12) Patent Application Publication
(10) Pub. No.: US 2026/0184912 A1
(43) Pub. Date: Jul. 2, 2026

(54) RESIN COMPOSITION, ARTICLE MADE THEREFROM, AND USE THEREOF

(71) Applicant: ELITE ELECTRONIC MATERIAL (KUNSHAN) CO., LTD., Kunshan City (CN)

(72) Inventors: Zheng JIA, Kunshan City (CN); Rongtao WANG, Kunshan City (CN); Yan ZHANG, Kunshan City (CN); Xueyan JIANG, Kunshan City (CN)

(73) Assignee: ELITE ELECTRONIC MATERIAL (KUNSHAN) CO., LTD., Kunshan City (CN)

(21) Appl. No.: 19/089,769

(22) Filed: Mar. 25, 2025

(30) Foreign Application Priority Data
Dec. 31, 2024 (CN) 202412000342.X

(51) Int. Cl. C08L 55/04; C08K 7/26; H05K 1/03

(52) U.S. Cl. CPC C08L 55/04; C08K 7/26; H05K 1/0373; C08K 2201/006; C08L 2203/20; C08L 2205/025; C08L 2205/035; H05K 2201/0209; H05K 2201/0263

(57) ABSTRACT

The present disclosure relates to a resin composition, an article made therefrom, and a use thereof. The resin composition comprises: 100 parts by weight of a thermosetting resin and 100 to 300 parts by weight of an inorganic filler; the resin composition has an organic volatile matters as measured by reference to IPC-TM-650 2.4.24.6 of ≤2.0%, the resin composition has a shear viscosity variation rate as measured by reference to GB/T 2794-2022 7.3 of 9 to 56%, and a resin cured product obtained by curing the resin composition has a dissipation factor at a frequency of 10 GHz as measured by reference to JIS C2565 of ≤0.0080. When the resin composition is applied in a resin filling process of a printed circuit board, the printed circuit board produced thereby achieves significant improvements in impedance stability, solder floating crack rate, and varnish scraping stability.

### CROSS-REFERENCE TO RELATED APPLICATIONS

This non-provisional application claims priority under 35 U.S.C. § 119(a) on Patent Application No(s). 202412000342.X filed in China on Dec. 31, 2024, the entire contents of which are hereby incorporated by reference.

### BACKGROUND

### 1. Technical Field

The present disclosure relates to a resin composition, an article made therefrom, and a use thereof, and particularly relates to a resin composition suitable for application in a resin filling process of printed circuit board (Printed Circuit Board, PCB).

### 2. Related Art

The resin filling process of PCB (also referred to as the resin filling process) is a novel technology invented to reduce PCB design dimensions to accommodate assembling components, thereby effectively improving the reliability and manufacturability of High Density Interconnect (HDI) substrates. At the same time, the use of resin filling technology also solves problems that cannot be resolved by using green oil hole-plugging process or lamination filling. By completely filling inner-layer blind/buried/through holes, slot/groove with resin, or by filling open areas in thick copper circuits with resin, followed by lamination, the process balances the conflict between the control of the laminated dielectric layer thickness and the design of inner-layer resin filling. For instance, resin filling of through-holes improves the reliability issues caused by green oil hole-plugging process.

However, in the prior art, the primary printing processes include simultaneous filling and printing process and the sequential filling followed by printing process. These processes impose stringent requirements on the shear viscosity variation rate of the resin composition (or referred to as ink) during application. Excessive variation in the shear viscosity of the resin composition leads to poor varnish scraping stability during the hole plugging printing process, thereby resulting in uneven hole plugging of the resin composition. Furthermore, as the demand for printed circuit boards for high-frequency, high-speed information transmission increases, the dissipation factor of PCB base material becomes increasingly lower. However, the resin composition used in the prior art's filling process still exhibits a relatively high dissipation factor, resulting in poor compatibility with the base material and inferior impedance stability in the PCB. In addition, the high organic volatile matters in the resin composition of the prior art leads to a high solder floating crack rate in PCBs after resin filling.

Therefore, there is an urgent need to develop a resin composition that has a moderate viscosity and a low shear viscosity variation rate, a long varnish shelflife, a low organic volatile matters, a low dissipation factor, a low water absorption ratio, a low Z-axis percent of thermal expansion, and a high copper foil peeling strength, and an excellent impedance stability of PCBs, a low solder floating crack rate of PCBs, and a superior varnish scraping stability during the resin filling process to meet the demands of high-frequency, high-speed information transmission in printed circuit boards.

### SUMMARY

The main purpose of the present disclosure is to provide a resin composition, an article manufactured from the resin composition, and a use of the resin composition in a resin filling process of a printed circuit board (e.g., one or more of a hole plugging process of a printed circuit board, a groove filling process of a printed circuit board, or a circuit filling process of a printed circuit board) to solve at least one of the aforementioned technical problems.

A first aspect of the present disclosure provides a resin composition, including the following components:
100 parts by weight of a thermosetting resin and 100 to 300 parts by weight of an inorganic filler;
the resin composition has an organic volatile matters as measured by reference to IPC-TM-650 2.4.24.6 of less than or equal to 2.0%,
the resin composition has a shear viscosity variation rate as measured by reference to GB/T 2794-2022 7.3 of 9 to 56%, and
a resin cured product obtained by curing the resin composition has a dissipation factor at a frequency of 10 GHz as measured by reference to JIS C2565 of less than or equal to 0.0080.

In the present disclosure, the resin composition that simultaneously meets the above three performance characteristics, when applied in the resin filling process of the printed circuit board, significantly improves the impedance stability, solder floating crack rate, and varnish scraping stability of the manufactured printed circuit board.

Preferably, the resin composition has the organic volatile matters as measured by reference to IPC-TM-650 2.4.24.6 of less than or equal to 0.5%, and
a resin cured product obtained by curing the resin composition has the dissipation factor at a frequency of 10 GHz as measured by reference to JIS C2565 of less than or equal to 0.0041.

Preferably, based on a total inorganic filler weight of 100 wt %, the inorganic filler includes 50 to 100 wt % silica, more preferably 80 to 100 wt % silica.

Preferably, based on a total inorganic filler weight of 100 wt %, the inorganic filler includes 2 to 17 wt % surface-porous silica, more preferably 2 to 12 wt % surface-porous silica.

Preferably, the surface-porous silica has a maximum particle size of 5 to 20 μm.

Preferably, the surface-porous silica has a specific surface area of 40 to 200 m²/g.

Preferably, the surface-porous silica has a maximum particle size of 5 to 15.9 μm.

Preferably, the surface-porous silica has a specific surface area of 103 to 200 m²/g.

Preferably, the thermosetting resin includes any one of a polyolefin, an acrylate ester compound, a maleimide resin, an organic silicone resin, a polyphenylene ether resin, a benzoxazine resin, an epoxy resin, an active ester, a phenol resin, and a cyanate ester resin, or a combination thereof.

Preferably, the resin composition does not include an organic solvent.

Preferably, the thermosetting resin includes (A) a maleic anhydride-modified polyolefin and (B) a multifunctional (meth)acrylate monomer and/or its oligomer; and
the inorganic filler includes (C) a surface-porous silica and (D) a non-porous silica.

Preferably, the weight ratio of (A) the maleic anhydride-modified polyolefin:(B) the multifunctional (meth)acrylate monomer and/or its oligomer:(C) the surface-porous silica:(D) the non-porous silica is 100:(30 to 90):(10 to 30):(150 to 350).

Preferably, the weight ratio of (C) the surface-porous silica to (D) the non-porous silica is from (1:5) to (1:35), more preferably from (1:8) to (1:35).

Preferably, the resin composition further includes at least one of a flame retardant, a curing accelerator, a polymerization inhibitor, a coloring agent, a surfactant, and a toughening agent, or a combination thereof.

A second aspect of the present disclosure provides an article manufactured from the above resin composition, the article comprises a prepreg, a resin film, a laminate, or a printed circuit board.

A third aspect of the present disclosure provides an article manufactured from the above resin composition, the article comprises a resin cured product obtained by curing the resin composition.

A fourth aspect of the present disclosure provides a printed circuit board produced by employing the above resin composition in a resin filling process of a printed circuit board, the printed circuit board has one or more of the following properties:
a solder floating crack rate in a resin cured product area of a printed circuit board as measured by reference to IPC-TM-650 2.4.13.1 of 0%;
an impedance amplitude in a resin cured product area of a printed circuit board as measured by a network analyzer of less than or equal to 10%; and
a continuous varnish scraping time of greater than or equal to 15 minutes during the resin filling process of the printed circuit board.

A fifth aspect of the present disclosure provides a use of the above resin composition applied in a resin filling process of a printed circuit board.

Preferably, the resin filling process of the printed circuit board includes one or more of a hole plugging process of a printed circuit board, a groove filling process of a printed circuit board, or a circuit filling process of a printed circuit board.

Preferably, in the hole plugging process of the printed circuit board, at least one hole of the printed circuit board is filled with a resin cured product of the resin composition; and/or
in the groove filling process of the printed circuit board, at least one groove of the printed circuit board is filled with a resin cured product of the resin composition; and/or
in the circuit filling process of the printed circuit board, at least one circuit open area of the printed circuit board is covered with a resin cured product of the resin composition.

Advantageous effects of the present disclosure:

The resin composition of the present disclosure, which simultaneously satisfies the organic volatile matters of ≤2.0%, the shear viscosity variation rate of 9 to 56%, and the dissipation factor of ≤0.0080, when used in a resin filling process of a printed circuit board to produce a printed circuit board, results in significant improvements in the impedance stability, solder floating crack rate, and varnish scraping stability of the printed circuit board. Moreover, the resin composition of the present disclosure, or various articles containing the resin cured product prepared therefrom, may simultaneously exhibit a low organic volatile matters, a low shear viscosity variation rate, and a low dissipation factor, and preferably achieve improvements in at least one of the following properties: the varnish shelf life, the copper foil peeling strength, the water absorption ratio, or the Z-axis percent of thermal expansion, and may satisfy the requirements for printed circuit boards in high-frequency, high-speed information transmission.

### DETAILED DESCRIPTION

In order to enable a person skilled in the art to clearly and correctly understand the technical content of the present disclosure, general explanations and definitions of the terms and symbols used herein is provided below. Unless otherwise specified, all terms and symbols (including scientific terms, technical terms, and general symbols, wherein general symbols include common mathematical, physical, and chemical symbols, etc.)

used in the present disclosure have the same meaning as commonly understood by a person skilled in the art. In the case of conflict, the definitions set forth herein shall prevail.

In the present disclosure, the terms “comprise”, “include”, “have”, “contain,” or the like belong to open-ended transitional phrase. Unless otherwise specified, other parts may also be included when using the terms.

In the present disclosure, the terms “at least one of or a combination thereof”, “any one of or a combination thereof”, “any one or a combination thereof”, and “one or more of” shall be interpreted as “using any one of the listed elements alone”, “using any two of the listed elements in combination”, or “using any three or more of the listed elements in combination”.

In the present disclosure, a number range expressed by “equal to”, “=”, “greater than or equal to”, “≥”, “less than or equal to”, “≤,” to “˜,”, “-”, “or more”, or “or less” should be interpreted as including the endpoints values. Additionally, the interpretation should cover all possible subranges and individual values within the range (the numeric type includes, but not limited to, integers, decimals, and fractions). For instance, a number range expressed as “equal to 3.0”, “=3.0”, “greater than or equal to 3.0”, “≥3.0”, “less than or equal to 3.0”, “≤3.0”, “3.0 or more”, or “3.0 or less” all include the endpoint value “3.0;” a number range expressed as “3.0 to 6.0”, “3.0˜6.0”, “3.0-6.0” all include the endpoint values “3.0” and “6.0”, and should be understood to include, but not be limited to, subranges such as 3.0-5.0, 4.0-6.0, and 5.0-6.0, as well as individual values such as 3.0, 4.0, 5.0, 5.5, and 6.0.

In the present disclosure, a number range expressed as “greater than,” “>,” “less than,” or “<” should be interpreted as excluding the endpoint values. For instance, a number range expressed as “greater than 3.0,” “>3.0,” “less than 3.0,” or “<3.0” all exclude the endpoint value “3.0.”

In the present disclosure, the numerical values have a degree of accuracy, which is determined by using the round off method.

In the present disclosure, “unsaturated carbon-carbon double bond-containing” means “a group containing unsaturated C═C double bond group”, such as, but not limited to, vinyl group, vinylbenzyl group, (meth)acryloyl group, allyl group, or a combination thereof. Among them, “vinyl group” should be interpreted as including vinyl group and vinylidene group, and “(meth)acryloyl group” should be interpreted as including acryloyl group and methacryloyl group.

In the present disclosure, functional groups, such as alkyl group and alkenyl group, should be interpreted as including various isomers thereof. For instance, “alkyl group” refers to a group derived from an aliphatic hydrocarbons and includes straight chain, branched, or cyclic groups. For a further example, propyl group should be interpreted as including n-propyl group and isopropyl group.

In the present disclosure, “monomer” or “compound” should be interpreted as including various isomers thereof, such as, but not limited to, structural isomers and stereoisomer, etc.

In the present disclosure, “part(s) by weight” should be interpreted as relative part(s) by weight, which may be any weight unit, such as but not limited to kilogram, gram, pound, etc. For instance, 100 parts by weight of the thermosetting resin means 100 kilograms of the thermosetting resin or 100 pounds of the thermosetting resin.

In the present disclosure, wt % refers to weight (or mass) percentage.

In the present disclosure, mil is a unit of thickness, where 1 mil is approximately equal to 25.4 micrometers, ounce is also a unit of thickness, where 1 ounce is approximately equal to 35 micrometers.

In the present disclosure, the monomer refers to a molecule capable of forming a polymer through covalent bonding with molecules of the same or different types.

In the present disclosure, the polymer refers to the product formed by the polymerization reaction of the monomer(s); the polymer may include a copolymer, a homopolymer, etc., but the present disclosure is not limited thereto. Unless otherwise specified, the degree of polymerization (conversion rate) of the polymer is not limited. For instance, it may be a fully polymerized polymer (with a conversion rate of 100%) or a partially polymerized polymer (with a conversion rate between, for example, but not limited to, between 10% and 99%, and it may also be referred to as a “prepolymer” as used in the present disclosure). The molecular weight of the polymer is not limited. For example, a polymer formed by 2 to 20 repeating units is referred to as an oligomer (or low polymer). Generally, an oligomer is a polymer formed by 2 to 5 repeating units.

In the present disclosure, the term copolymer refers to a product formed by two or more different monomers via polymerization, including random copolymers, alternating copolymers, graft copolymers, or block copolymers, but the present disclosure is not limited thereto.

Specific detailed descriptions and embodiments are used to describe the present disclosure below. The embodiments are merely illustrative of preferred detailed descriptions and do not limit the scope of the present disclosure.

As describe above, the present disclosure provides a resin composition, including the following components:
100 parts by weight of a thermosetting resin and 100 to 300 parts by weight of an inorganic filler;
the resin composition has an organic volatile matters as measured by reference to IPC-TM-650 2.4.24.6 of less than or equal to 2.0%,
the resin composition has a shear viscosity variation rate as measured by reference to GB/T 2794-2022 7.3 of 9 to 56%, and
a resin cured product obtained by curing the resin composition has a dissipation factor at a frequency of 10 GHz as measured by reference to JIS C2565 of less than or equal to 0.0080.

Preferably, the present disclose provides a resin composition applied in a resin filling process of a printed circuit board, including the following components:
100 parts by weight of the thermosetting resin and 100 to 300 parts by weight of the inorganic filler;
the resin composition has the organic volatile matters as measured by reference to IPC-TM-650 2.4.24.6 of less than or equal to 2.0%,
the resin composition has the shear viscosity variation rate as measured by reference to GB/T 2794-2022 7.3 of 9 to 56%, and
the resin cured product obtained by curing the resin composition has the dissipation factor at the frequency of 10 GHz as measured by reference to JIS C2565 of less than or equal to 0.0080.

Preferably, the resin cured product obtained by curing the resin composition has the dissipation factor at the frequency of 10 GHz as measured by reference to JIS C2565 of less than or equal to 0.0060, and more preferably, the dissipation factor (Df) of less than or equal to 0.0041. A lower dissipation factor corresponds to better PCB impedance stability after the resin filling.

Preferably, the resin composition has the shear viscosity variation rate as measured by reference to GB/T 2794-2022 7.3 of 12 to 41%. A lower shear viscosity variation rate corresponds to better varnish scraping stability during the resin filling process.

Preferably, the resin composition has the organic volatile matters as measured by reference to IPC-TM-650 2.4.24.6 of less than or equal to 1.0%, and more preferably, the organic volatile matters of less than or equal to 0.5%.

In one embodiment of the present disclosure, the inorganic filler includes, but is not limited to, any one of silica (in fused, non-fused, porous, or hollow forms), aluminum oxide, aluminum hydroxide, magnesium oxide, magnesium hydroxide, iron oxide, boron oxide, zinc oxide, zirconium oxide, mica, boehmite, aluminum nitride, boron nitride, aluminum silicon carbide, silicon carbide, titanium dioxide, zinc molybdate, calcium molybdate, magnesium molybdate, ammonium molybdate, zinc molybdate-modified talc, calcined talc, talc, silicon nitride, zirconium tungstate, petalite, and calcined kaolin, or a combination thereof.

The inorganic filler may be spherical, fibrous, plate-like, particulate, flake-like, rod-shaped, or whisker-like, and preferably spherical. The inorganic filler may also have various morphologies, including solid, hollow, or surface-porous, etc. Optionally, the inorganic filler may be pretreated with silane coupling agents. In addition, the color of the inorganic filler is not particularly limited and may be white, black, light yellow, or other colors, but the present disclosure is not limited thereto. The preparation method of the inorganic filler is also not particularly limited; For instance, the preparation of spherical silica (referred to as “spherical silica”) may include a melting method, a chemical synthesis method or a directly combustion method, etc. Preferably, based on 100 wt % of the total inorganic filler, the inorganic filler includes 50 to 100 wt % silica, and more preferably, the inorganic filler includes 80 to 100 wt % silica.

Preferably, based on 100 wt % of the total inorganic filler, the inorganic filler includes 2 to 17 wt % surface-porous silica, and more preferably, the inorganic filler includes 2 to 12 wt % surface-porous silica.

In the present disclosure, the surface-porous silica is surface-porous solid-core silica, including but not limited to surface-porous treated solid silica, which may be either self-manufactured or commercially available. Preferably, the surface-porous silica is spherical surface-porous solid-core silica, rod-shaped surface-porous solid-core silica, or a combination thereof.

In the present disclosure, the maximum particle size (D100 particle size) of the surface-porous silica ranges, for example but not limited to, from 5 to 20 μm, and the specific surface area ranges, for example but not limited to, from 40 to 200 m²/g. Preferably, the D100 particle size of the surface-porous silica ranges from 5 to 15.9 μm, and the specific surface area ranges from 103 to 200 m²/g.

In the present disclosure, the surface-porous silica may be either a single type of surface-porous solid silica or a mixture of two or more different types of surface-porous solid silica. Also, the preparation methods for the surface-porous silica may be various known preparation methods.

In the present disclosure, the type and amount of the thermosetting resin are not particularly limited and can be adjusted according to the properties of the resin composition and the resin cured product obtained by curing the resin composition. As long as the resin cured product can achieve the dissipation factor less than or equal to 0.0080, the resin composition can achieve the shear viscosity variation rate of 9 to 56% and the organic volatile matters less than or equal to 2.0%, it is acceptable.

In a preferred embodiment, the thermosetting resin includes any one of a polyolefin, an acrylate ester compound, a maleimide resin, an organic silicone resin, a polyphenylene ether resin, a benzoxazine resin, an epoxy resin, an active ester, a phenol resin, and a cyanate ester resin, or a combination thereof.

In a preferred embodiment, based on 100 wt % of the thermosetting resin, each of the content of the polyolefin and the acrylate ester compound is independently 1 to 99 wt %, for example but not limited to 1 wt %, 5 wt %, 10 wt %, 15 wt %, 20 wt %, 25 wt %, 50 wt %, or 99 wt %, and each of the content of the maleimide resin, the organic silicone resin, the polyphenylene ether resin, the benzoxazine resin, the epoxy resin, the active ester, the phenol resin, and the cyanate ester resin is independently 0 to 98 wt %, for example but not limited to 0 wt %, 1 wt %, 5 wt %, 10 wt %, 15 wt %, 20 wt %, 25 wt %, 50 wt %, or 98 wt %.

In a preferred embodiment, based on 100 wt % of the thermosetting resin, the thermosetting resin includes 25 to 80 wt % of the polyolefin and 20 to 75 wt % of the acrylate ester compound.

The polyolefin in the thermosetting resin may be a single type of polyolefin or a mixture of two or more different types of the polyolefins. Preferably, the content of the polyolefin of the thermosetting resin is 25 to 80 wt %, and more preferably is 26 to 77 wt %.

In one embodiment of the present disclosure, the polyolefin includes a maleic anhydride-modified polyolefin, other polyolefins different from the maleic anhydride-modified polyolefin, or a combination thereof, preferably, the content of the maleic anhydride-modified polyolefin of the polyolefin is 75 to 100 wt % The modification method involving maleic anhydride modification may be any known chemical modification method in the field, including but not limited to addition polymerization modification, and the addition polymerization modification includes but is not limited to free radical polymerization, cationic polymerization, anionic polymerization, or coordination polymerization. For instance, maleic anhydride monomers undergo addition polymerization with one or more olefin polymers to produce maleic anhydride-modified polyolefin. Alternatively, the maleic anhydride monomers undergo addition polymerization with one or more olefin monomers to form random, alternating, block, or graft copolymers, i.e., maleic anhydride-modified polyolefin.

The types of the olefin polymers and the olefin monomers suitable for the aforementioned modification methods are not particularly limited and may include various known olefin polymers and olefin monomers in the art. In other words, the maleic anhydride-modified polyolefin of the present disclosure may be obtained by modifying various polyolefins or olefin monomers using the maleic anhydride.

The maleic anhydride-modified polyolefin of the resin composition may be a single type of the maleic anhydride-modified polyolefin or a mixture of two or more different types of the maleic anhydride-modified polyolefins.

The maleic anhydride-modified polyolefin includes, but is not limited to, any one of a maleic anhydride-adducted polybutadiene, a maleic anhydride-adducted polyisoprene, a maleic anhydride-adducted styrene-butadiene copolymer, a maleic anhydride-adducted styrene-isoprene copolymer, a maleic anhydride-styrene copolymer, or a combination thereof.

The maleic anhydride-styrene copolymer may include various maleic anhydride-styrene copolymers known in the art, wherein the ratio of styrene (St) to maleic anhydride (MA) may be 1/1, 2/1, 3/1, 4/1, 6/1, 8/1, or 12/1. Specific examples include, but are not limited to, maleic anhydride-styrene copolymers XIRAN-1000, XIRAN-2000, XIRAN-3000, XIRAN EF-40, and XIRAN EF-80, which are commercially available from Aurorium. In the present disclosure, polyolefins other than the maleic anhydride-modified polyolefins include, but are not limited to, a polybutadiene, a polyisoprene, a styrene-butadiene copolymer, a styrene-isoprene copolymer, a styrene-butadiene-divinylbenzene polymer, a vinyl-polybutadiene-urethane polymer, a polymethyl styrene, a hydrogenated polybutadiene, a hydrogenated polyisoprene, a hydrogenated styrene-butadiene-divinylbenzene polymer, a hydrogenated styrene-butadiene copolymer, a hydrogenated styrene-isoprene copolymer, an epoxy-containing polybutadiene, a divinylbenzene-styrene-ethylstyrene copolymer, and an ethylene-divinylbenzene-styrene copolymer, or a combination thereof.

The divinylbenzene-styrene-ethylstyrene copolymer used in the present disclosure may include various divinylbenzene-styrene-ethylstyrene copolymers disclosed in U.S. Patent Publication US20070129502A1, the entire contents of which are incorporated herein by reference.

The acrylate ester compound in the thermosetting resin includes, but is not limited to: any one of monofunctional (meth)acrylate monomer and/or its oligomer containing one (meth)acrylate group per molecule, multifunctional (meth)acrylate monomer and/or its oligomer containing two or more (meth)acrylate groups per molecule, or a combination thereof. In the present disclosure, the acrylate ester compound may include one or more (meth)acrylate monomers, or the acrylate ester compound may include one or more oligomers of (meth)acrylates, or the acrylate ester compound may include a mixture of one or more (meth)acrylate monomers and one or more oligomers of (meth)acrylates. Preferably, the content of the acrylate ester compound of the thermosetting resin is 20 to 75 wt %, more preferably 23 to 56 wt %. Preferably, the multifunctional (meth)acrylate monomer and/or its oligomer of the acrylate ester compound are 90 to 100 wt %.

The acrylate ester compounds are in a liquid state at room temperature. The relative molecular mass (Mr) of the acrylate ester compounds is less than or equal to 2000, and the weight-average molecular weight (Mw) of the oligomers polymerized from the monofunctional (meth)acrylate monomers or the multifunctional (meth)acrylate monomers is less than or equal to 2000.

The monofunctional (meth)acrylate monomer and/or itsoligomerinclude, but are not limited to any one of a (meth)acrylate methyl ester and/or its oligomer thereof, a (meth)acrylate ethyl ester and/or its oligomer, a (meth)acrylate propyl ester and/or its oligomer, and a (meth)acrylate butyl ester and/or its oligomer, or a combination thereof.

The multifunctional (meth)acrylate monomer and/or its oligomer include, but are not limited to any one of difunctional acrylate monomer and/or its oligomer, trifunctional acrylate monomer and/or its oligomer, tetrafunctional acrylate monomer and/or its oligomer, pentafunctional acrylate monomer and/or its oligomer, hexafunctional acrylate monomer and/or its oligomer, or a combination thereof, and these multifunctional (meth)acrylate monomer and/or its oligomer may be self-manufactured or commercially available from Sartomer.

Preferably, the multifunctional (meth)acrylate monomer includes two or three (meth)acrylate groups.

The multifunctional (meth)acrylate monomer and/or its oligomer include, but are not limited to any one of a tricyclodecane dimethanol di(meth)acrylate and/or its oligomer, a dioxane glycol di(meth)acrylate and/or its oligomer, a dipropylene glycol di(meth)acrylate and/or its oligomer, a tris(2-hydroxyethyl) isocyanurate tri(meth)acrylate and/or its oligomer, a pentaerythritol tri(meth)acrylate and/or its oligomer, a pentaerythritol tetra(meth)acrylate and/or its oligomer, a di-trimethylolpropane tetra(meth)acrylate and/or its oligomer, a di-pentaerythritol penta(meth)acrylate and/or its oligomer, a di-pentaerythritol hexa(meth)acrylate and/or its oligomer, or a combination thereof.

Compared to (meth)acrylate monomer and/or its oligomer with only one (meth)acrylate group, the multifunctional (meth)acrylate monomer and/or its oligomer described in the present disclosure exhibit higher crosslinking density, resulting in superior heat resistance of the manufactured articles.

The multifunctional (meth)acrylate monomers or its oligomer has a glass transition temperature (Tg) of greater than or equal to 80° C. after being heated to cure completely, that is, the cured product of the multifunctional (meth)acrylate monomer or its oligomer has a glass transition temperature (Tg) of greater than or equal to 80° C. Preferably, The multifunctional (meth)acrylate monomer or its oligomer has a glass transition temperature (Tg) of greater than or equal to 90° C. after being heated to cure completely. More preferably, the multifunctional (meth)acrylate monomer or its oligomerhas a glass transition temperature of greater than or equal to 150° C. after being heated to cure completely.

In the present disclosure, the acrylate ester compound not only participates in crosslinking reactions but also serves to dissolve and dilute the resin composition. Preferably, the resin composition of the present disclosure does not include additional organic solvents. The manufactured resin composition has very low volatile matters, moderate viscosity, and stable varnish shelf life.

Preferably, the resin composition does not include organic solvents. The resin composition does not include any one of an alcohol-based, an ether-based, a ketone-based, an aromatic hydrocarbon-based, an ester-based, or an amide-based organic solvents, or a combination thereof. The organic solvents include, but are not limited to: methanol, ethanol, ethylene glycol monomethyl ether, acetone, butanone (also referred to as methyl ethyl ketone), methyl isobutyl ketone, cyclohexanone, N-methylpyrrolidone, toluene, xylene, methoxyethyl acetate, ethoxyethyl acetate, propoxyethyl acetate, ethyl acetate, propylene glycol methyl ether acetate, dimethyl formamide, dimethyl acetamide, or a mixed solvent thereof.

The maleimide resin in the thermosetting resin may be various maleimide resin known in the art, Preferably, the content of the maleimide resin is 0 to 15 wt %, more preferably 3 to 11 wt %.

Specific examples of the maleimide resin include, but are not limited to any one of 4,4′-diphenylmethane bismaleimide, polyphenylmethane maleimide (also referred to as oligomer of phenylmethane maleimide), bisphenol A diphenyl ether bismaleimide, 3,3′-dimethyl-5,5′-diethyl-4,4′-diphenylmethane bismaleimide, 3,3′-dimethyl-5,5′-dipropyl-4,4′-diphenylmethane bismaleimide, m-phenylene bismaleimide, 4-methyl-1,3-phenylene bismaleimide, 1,6-bismaleimide-(2,2,4-trimethyl) hexane, N-2,3-xylylmaleimide, N-2,6-xylylmaleimide, N-phenylmaleimide, vinyl benzyl maleimide (VBM), indane structure-containing maleimide, isopropyl and meta-arylene structure-containing maleimide, biphenyl alkylidene structure-containing maleimide, maleimide with aliphatic structure having 10 to 50 carbon atoms, or a combination thereof.

Unless otherwise specified, the aforementioned maleimide resin should be interpreted to include modified forms thereof, for example, but not limited to, prepolymers of diallyl compounds and maleimide resin, prepolymers of diamines and maleimide resin, prepolymers of multifunctional amines and maleimide resin, prepolymers of acidic phenol compounds and maleimide resin, prepolymers of cyanate esters and maleimide resin, or a combination thereof.

Specific examples of the maleimide resin include, but are not limited to, maleimide resin products BMI-1000, BMI-1000H, BMI-1100, BMI-1100H, BMI-2000, BMI-2300, BMI-3000, BMI-3000H, BMI-4000, BMI-5000, BMI-5100, BMI-TMH, BMI-7000 and BMI-7000H available from Daiwakasei Industry Co., Ltd., or maleimide resin products BMI-70 or BMI-80 available from K.I Chemical Co., Ltd., maleimide resin products MIR-3000 or MIR-5000 available from Nippon Kayaku.

Maleimide with aliphatic structure having 10 to 50 carbon atoms, also referred to as imide-extended maleimide resin, may include various imide-extended maleimide resins disclosed in the Taiwan Patent Application Publication No. 200508284A, all of which are incorporated herein by reference in their entirety. Specific examples of maleimide with an aliphatic structure having 10 to 50 carbon atoms suitable for the present disclosure may include, but are not limited to, maleimide resin products BMI-689, BMI-1400, BMI-1500, BMI-1700, BMI-2500, BMI-3000, BMI-5000 and BMI-6000 available from Designer Molecules Inc. The structure of maleimide with an aliphatic structure having 10 to 50 carbon atoms includes maleimide groups and aliphatic groups bonded to the maleimide groups.

Isopropyl and meta-arylene structure-containing maleimide includes maleimide shown in Formula (1), biphenyl alkylidene structure-containing maleimide includes maleimide shown in Formula (2), and indane structure-containing maleimide includes maleimide shown in Formula (3).

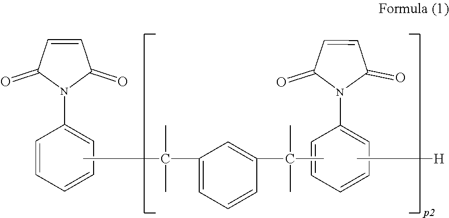

In Formula (1), p₂ represents the average degree of polymerization, and p₂ may be a value from 1 to 10.

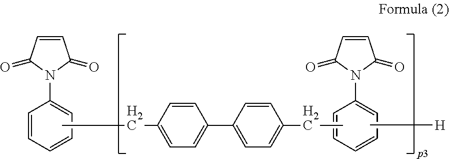

In Formula (2), p₃ represents the average degree of polymerization, and p₃ may be a value from 1 to 10.

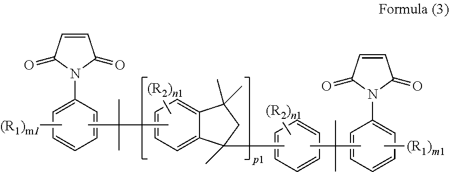

In Formula (3), R₁ and R₂ are each independently the same or different, and independently represent a C₁-C₁₀ alkyl, m1 represents the number of R1 groups, and m¹ is independently an integer from 0 to 4, n1 represents the number of R2 groups, and n1 is independently an integer from 0 to 3, and p₁ represents the average degree of polymerization, and p₁ may be a value from 0.5 to 20.

Unless otherwise specified, the cyanate ester-modified maleimide resin (also referred to as a maleimide-triazine resin) used in the present disclosureis not particularly limited and may be various maleimide triazine resin known in the art. Specific examples include, but are not limited to, a maleimide triazine resin obtained by polymerizing a maleimide resin and a bisphenol A cyanate ester resin, a maleimide triazine resin obtained by polymerizing a maleimide resin and a bisphenol F cyanate ester resin, a maleimide triazine resin obtained by polymerizing a maleimide resin and a phenol novolac cyanate ester resin, a maleimide triazine resin obtained by polymerizing a maleimide resin and a dicyclopentadiene-containing cyanate ester resin. The maleimide triazine resin may be obtained by polymerizing the maleimide resin and the aforementioned cyanate ester resin in any molar ratio, for example, the molar ratio of maleimide resin to cyanate ester resin may be 1:1 to 1:10, for example, but not limited to, 1:1, 1:2, 1:4, 1:6, 1:8, 1:10.

In the present disclosure, the organic silicone resin may be various organic silicone resin known in the art, preferably, the content of the organic silicone resin of the thermosetting resin is 0 to 10 wt %. Specific examples include, but are not limited to, a polyalkyl organic silicone resin, a polyaryl organic silicone resin, a polyalkylaryl organic silicone resin, a modified organic silicone resin, or a combination thereof. The modified organic silicone resin includes, but is not limited to, an amino-modified organic silicone resin, an epoxy-modified organic silicone resin, a methacryloyl-modified organic silicone resin, a hydroxyl-modified organic silicone resin, a carboxyl-modified organic silicone resin or a combination thereof. Preferably, for example, the amino-modified organic silicone resin suitable for the present disclosure may be amino-modified organic silicone resin products KF-8010, X-22-161A, X-22-161B, KF-8012, KF-8008, X-22-9409, X-22-1660B-3 available from Shin-Etsu Chemical Co., Ltd., amino-modified organic silicone resin products BY-16-853U, BY-16-853, BY-16-853B available from Toray-Dow corning Co., Ltd., amino-modified organic silicone resin products XF42-C5742, XF42-C6252, XF42-C5379 available from Momentive Performance Materials JAPAN LLC or a combination thereof. For instance, the epoxy-modified organic silicone resin suitable for the present disclosure may be products of X-22-163 series available from Shin-Etsu Chemical Co., Ltd. For instance, the methacryloyl-modified organic silicone resin suitable for the present disclosure may be products of X-22-164 series available from Shin-Etsu Chemical Co., Ltd.

In the present disclosure, a polyphenylene ether resin suitable for the invention is not particularly limited and may be various polyphenylene ether resin known in the art, and may be one or more commercially available product, self-manufactured product, or a combination thereof, for example, the polyphenylene ether resin include, but is not limited to, a hydroxy polyphenylene ether resin (e.g., SA90, SA120, available from Saudi Basic Industries Corporation (SABIC)), an unsaturated carbon-carbon double bond-containing polyphenylene ether resin, or a combination thereof. The unsaturated carbon-carbon double bond-containing polyphenylene ether resin includes, but is not limited to, any one of a vinylbenzyl polyphenylene ether resin, a (meth)acrylate polyphenylene ether resin, a vinyl polyphenylene ether resin, an allyl polyphenylene ether resin, or a combination thereof. Preferably, the polyphenylene ether resin of the thermosetting resin is 0 to 10 wt %.

The unsaturated carbon-carbon double bond-containing polyphenylene ether resin described in the present disclosure has unsaturated carbon-carbon double bonds and a phenyl ether backbone, wherein the unsaturated carbon-carbon double bonds serve as reactive functional groups that undergo self-polymerization upon heating or undergo free radical polymerization with other unsaturated components in the resin composition, and ultimately being crosslinked and cured. Preferably, the unsaturated carbon-carbon double bond-containing polyphenylene ether resin includes the unsaturated carbon-carbon double bond-containing polyphenylene ether resin where the phenyl ether backbone is substituted with 2,6-dimethyl. The methyl substitution results in steric hindrance, making it difficult for the oxygen atom of the ether to form hydrogen bonds or van der Waals forces, thereby reducing moisture absorption.

The unsaturated carbon-carbon double bond-containing polyphenylene ether resin includes, but is not limited to, a vinylbenzyl polyphenylene ether resin with a number average molecular weight of about 1200 (e.g., OPE-2st 1200, available from Mitsubishi Gas Chemical Co., Inc.), a vinylbenzyl group-containing polyphenylene ether resin with a number average molecular weight of about 2200 (e.g., OPE-2st 2200, available from Mitsubishi Gas Chemical Co., Inc.), a vinylbenzyl group-containing polyphenylene ether resin with a number average molecular weight of about 2400 to 2800 (e.g., vinylbenzyl group-containing bisphenol A polyphenylene ether resin), a (meth)acryloyl groupcontaining polyphenylene ether resin with a number average molecular weight of about 1900 to 2300 (e.g., SA9000, available from Saudi Basic Industries Corporation (SABIC)), a vinyl group-containing polyphenylene ether resin with a number average molecular weight of about 2200 to 3000 or a combination thereof, but the present disclosure is not limited thereto. Among them, the vinyl group-containing polyphenylene ether resin may include various polyphenylene ether resins disclosed in the US Patent Application Publication No. 20160185904 A1, all of which are incorporated herein by reference in their entirety. The vinylbenzyl group-containing polyphenylene ether resin includes, but is not limited to, a vinylbenzyl group-containing biphenyl polyphenylene ether resin, a vinylbenzyl group-containing bisphenol A polyphenylene ether resin or a combination thereof.

The benzoxazine resin suitable for the present disclosure may be various benzoxazine resins known in the art. Preferably, the content of the benzoxazine resin of the thermosetting resin is 0 to 10 wt %. For example, the benzoxazine resin comprises but is not limited to bisphenol A benzoxazine resin, bisphenol F benzoxazine resin, phenolphthalein benzoxazine resin, dicyclopentadiene benzoxazine resin, phosphorus-containing benzoxazine resin, diamine benzoxazine resin and phenyl group-modified, vinyl group-modified or allyl group-modified benzoxazine resin. Commercially available products LZ-8270 (phenolphthalein benzoxazine resin), LZ-8298 (phenolphthalein benzoxazine resin), LZ-82818 (bisphenol F benzoxazine resin) and LZ-82919 (bisphenol A benzoxazine resin) available from Huntsman, and PF-3500 (diaminodiphenyl ether benzoxazine resin) available from Chang Chun Plastics Co., Ltd, and HFB-2006M (phosphorus-containing benzoxazine resin) available from Showa High Polymer, and KZH-5031 (vinyl group-modified benzoxazine resin) and KZH-5032 (phenyl group-modified benzoxazine resin) available from Kolon Industries Inc. The diamine benzoxazine resin may be diaminodiphenylmethane benzoxazine resin, diaminodiphenyl ether benzoxazine resin, diaminodiphenyl sulfone benzoxazine resin, diaminodiphenyl sulfide benzoxazine resin or a combination thereof, but not limited thereto.

The epoxy resin suitable for the present disclosure may be various epoxy resin known in the art. Preferably, the content of the epoxy resin of the thermosetting resin is 0 to 10 wt %. For improving the thermal resistance of the resin composition, the epoxy resin includes, but is not limited to, any one of a bisphenol A epoxy resin, a bisphenol F epoxy resin, a bisphenol S epoxy resin, a bisphenol AD epoxy resin, a novolac epoxy resin, a trifunctional epoxy resin, a tetrafunctional epoxy resin, a multifunctional novolac epoxy resin, a dicyclopentadiene (DCPD) epoxy resin, a phosphorus-containing epoxy resin, a p-xylene epoxy resin, a naphthalene epoxy resin (e.g., a naphthol epoxy resin or a naphthylene ether epoxy resin), a benzofuran epoxy resin, a isocyanate-modified epoxy resin or a combination thereof. In the present disclosure, for example, the novolac epoxy resin may be a phenol novolac epoxy resin, a bisphenol A novolac epoxy resin, a bisphenol F novolac epoxy resin, a biphenyl novolac epoxy resin, a phenol benzaldehyde epoxy resin, a phenol aralkyl novolac epoxy resin or a o-cresol novolac epoxy resin. In the present disclosure, for example, the phosphorus-containing epoxy resin may be a DOPO (9,10-dihydro-9-oxa-10-phosphaphenanthrene-10-oxide) epoxy resin, a DOPO-HQ epoxy resin or a combination thereof. The DOPO epoxy resin may be one or more selected from a DOPO-containing phenol novolac epoxy resin, a DOPO-containing o-cresol novolac epoxy resin and a DOPO-containing bisphenol-A novolac epoxy resin. The DOPO-HQ epoxy resin may be one or more selected from DOPO-HQ-containing phenol novolac epoxy resin, DOPO-HQ-containing o-cresol novolac epoxy resin and DOPO-HQ-containing bisphenol-A novolac epoxy resin, but the present disclosure is not limited thereto.

The epoxy resin includes, but is not limited to, RE310S, RE410S (bisphenol A epoxy resins available from Nippon Kayaku Co., Ltd.), YD-128 (bisphenol A epoxy resins available from Nippon Steel Chemical Co., Ltd.), 828US, jER828EL, 825, 828EL (bisphenol A epoxy resins available from Mitsubishi Chemical Co., Ltd.), RE303S, RE304S, RE403S, RE404S (bisphenol F epoxy resins available from Nippon Kayaku Co., Ltd.), jE807, 1750 (bisphenol F epoxy resins available from Mitsubishi Chemical Co., Ltd.), HP4032, HP4032D, HP4032SS (naphthalene epoxy resins available from DIC Co., Ltd.), HP4032H (naphthalene epoxy resins available from DIC Co., Ltd.), EXA-7311, EXA-7311-G3, EXA-7311-G4, EXA-7311-G4S, HP-6000 (naphthylene ether epoxy resins available from DIC Co., Ltd.), HP-4700, HP-4710 (naphthalene tetrafunctional epoxy resins available from DIC Co., Ltd.), N-690 (cresol novolac epoxy resins available from DIC Co., Ltd.), N-695 (cresol novolac epoxy resins available from DIC Co., Ltd.), HP-7200, HP-7200HH, HP-7200H, HP-7200L (dicyclopentadiene epoxy resins available from DIC Co., Ltd.), and YX7700 (phenol aralkyl epoxy resins available from Mitsubishi Chemical Co., Ltd.).

The active ester suitable for the resin composition of the present disclosure may be various active polyester resins known in the art, including, but not limited to, various commercially available active polyester resins products. Specific examples include, but are not limited to, a dicyclopentadiene-containing polyester resin and a naphthalene ring-containing polyester resin, including, but not limited to, HPC-8000-65T or HPC-8150-62T active polyester resins available from DIC Co., Ltd. Preferably, the content of the active ester of the thermosetting resin is 0 to 10 wt %.

In the present disclosure, the phenol resin may be various phenol resins known in the art. Specific examples include, but are not limited to, any one of a novolac resin or a phenoxy resin, wherein the novolac resin includes a phenol novolac resin, an o-cresol novolac resin, a bisphenol A novolac resin, a naphthol novolac resin, a biphenyl novolac resin and a dicyclopentadiene phenol resin, or any combination thereof. The phenol resin suitable for the resin composition of the present disclosure may be various phenol resins known in the art, including, but not limited to, YP-50, YP50S, YP55, YP70, and YPB-43C (phenoxy resins available from Nippon Steel Chemical Co., Ltd.). Preferably, the content of the phenol resin of the thermosetting resin is 0 to 10 wt %.

In the present disclosure, the cyanate ester resin may be various cyanate ester resins known in the art, for example, compounds having an Ar—O—C≡N structure, wherein Ar may be a substituted or unsubstituted aromatic group. For improving the thermal resistance of the resin composition, specific examples include, but are not limited to, a novolac cyanate ester resin, a bisphenol A cyanate ester resin, a bisphenol F cyanate ester resin, a dicyclopentadiene-containing cyanate ester resin, a naphthalene-containing cyanate ester resin, a phenolphthalein cyanate ester resin, an adamantane cyanate ester resin, a fluorene cyanate ester resin or a combination thereof. Among them, the novolac cyanate ester resin may be a bisphenol A novolac cyanate ester resin, a bisphenol F novolac cyanate ester resin or a combination thereof. The cyanate ester resin may be cyanate ester resins Primaset PT-15, PT-30, PT-30S, PT-60, PT-60S, BA-200, BA-230S, BA-3000, BA-3000S, BA-4000, BA-4000S, DT-4000, DT-7000, ULL-950S, HTL-300, CE-320, LVT-50, LVT-100, LECy produced by and commercially available from Arxada AG, preferably, the content of the cyanate ester resin of the thermosetting resin is 0 to 10 wt %.

In a preferred embodiment, considering the improvement of the varnish shelf life of the resin composition, the resin composition of the present disclosure preferably includes:
(A) a maleic anhydride-modified polyolefin;
(B) a multifunctional (meth)acrylate monomer and/or its oligomer;
(C) a surface-porous silica;
(D) a non-porous silica.

Preferably, a content ratio of components (A):(B):(C):(D) is 100:(30 to 90):(10 to 30):(150 to 350).

In one embodiment, the content ratio of (C) the surface-porous silica to (D) the non-porous silica is (1:5) to (1:35), preferably (1:8) to (1:35).

The maleic anhydride-modified polyolefin, the multifunctional (meth)acrylate monomer and/or its oligomer, and the surface-porous silica are as described aforementioned.

The non-porous silica is silica that has no pores on either the surface or inside. Preferably, the non-porous silica is spherical silica with no pores on either the surface or inside.

Besides the aforementioned components, the resin composition of the disclosure may, as necessary, include any one of a flame retardant, a curing accelerator, a polymerization inhibitor, a coloring agent, a surfactant, and a toughening agent, or a combination of.

In one embodiment of the disclosure, the flame retardant may be various flame retardants known in the art, for example, including, but not limited to, a phosphorus-containing flame retardant or a bromine-containing flame retardant. The bromine-containing flame retardant preferably includes decabromodiphenylethane, and the phosphorus-containing flame retardant preferably includes hydroquinone bis-(diphenyl phosphate), bisphenol A bis-(diphenylphosphate), tri(2-carboxyethyl)phosphine (TCEP), trimethyl phosphate (TMP), dimethyl methyl phosphonate (DMMP), resorcinol bis(dixylenyl phosphate), RDXP (e.g., commercially available products PX-200, PX-201 and PX-202), phosphazene compounds (e.g., commercially available products SPB-100, SPH-100, which are the phosphazene compounds without unsaturated carbon-carbon double bonds, or alternatively, commercially available products SPV-100, which are allyl phosphazene compounds, or self-manufactured or commercially available vinyl phosphazene compounds), ammonium polyphosphate, melamine polyphosphate, 9,10-dihydro-9-oxa-10-phosphaphenanthrene-10-oxide (DOPO) and derivatives thereof or resins (e.g., di-DOPO compounds), diphenylphosphine oxide (DPPO) and derivatives thereof or resins (e.g., di-DPPO compounds), melamine cyanurate, and trishydroxyethyl isocyanurate, aluminium phosphinate (e.g., products OP-930 and OP-935) or a combination thereof.

The flame retardant may be a flame retardant available from Katayama Chemical Industries Co., Ltd., for example, including, but not limited to, V1, V2, V3, V4, V5, V7, S-2, S-4, E-4c, E-7c, E-8g, E-9g, E-10g, E-100, B-3, W-10, W-2h, W-20, W-30, W-40, OX-1, OX-2, OX-4, OX-6, OX-6+, OX-7, OX-7+, OX-13, BPE-1, BPE-3, HyP-2, API-9, CMPO, ME-20, C-1R, C-1S, C-3R, C-3S, or C-11R. The flame retardant of the present disclosure may include one or more of the flame retardant aforementioned. Unless otherwise specified, relative to 100 parts by weight of the thermosetting resin, the resin composition of the disclosure may further include 1 to 100 parts by weight of the flame retardant, preferably 1 to 50 parts by weight of the flame retardant, but the present disclosure is not limited thereto.

In one embodiment of the disclosure, the curing accelerator may include a catalyst, such as a Lewis base or a Lewis acid. The Lewis base may include one or more of imidazole, boron trifluoride-amine complex, ethyltriphenyl phosphonium chloride, 2-methylimidazole (2 MI), 2-phenyl-1H-imidazole (2PZ), 2-ethyl-4-methylimidazole (2E4MZ), triphenylphosphine (TPP) and 4-dimethylaminopyridine (DMAP). The Lewis acid may include metal salt compounds, such as metal salt compounds of manganese, iron, cobalt, nickel, copper and zinc, such as zinc octanoate or cobalt octanoate. The curing accelerator also includes a curing initiator, such as a peroxide capable of producing free radicals. The curing initiator includes dicumyl peroxide (DCP), tert-butyl peroxybenzoate, dibenzoyl peroxide (BPO), 2,5-dimethyl-2,5-di-(tert-butylperoxy)-3-hexyne (DYBP), di-tert-butyl peroxide (DTBP), bis(tert-butylperoxy isopropyl)benzene (BIBP), or a combination thereof. Relative to 100 parts by weight of the thermosetting resin, the resin composition of the disclosure may further comprise 0.001 to 20 parts by weight of the curing accelerator, preferably 0.01 to 15 parts by weight of the curing accelerator, more preferably 0.5 to 10 parts by weight of the curing accelerator, but not limited thereto.

In one embodiment of the disclosure, the polymerization inhibitor may include, but is not limited to, 1,1-diphenyl-2-picrylhydrazyl, methyl acrylonitrile, nitroxide-mediated radical, triphenylmethyl radicals, metal ion radical, sulfur radical (e.g., including but not limited to dithioester), hydroquinone, 4-methoxyphenol, p-methoxyphenol, p-benzoquinone, phenothiazine, β-phenylnaphthylamine, p-tert-butylcatechol, methylene blue, 4,4′-butylidenebis(6-tert-butyl-3-methylphenol), 2,2′-methylenebis(4-ethyl-6-t-butylphenol) or a combination thereof. For instance, the nitroxide-mediated radicals may include, but are not limited to, 2,2,6,6-tetramethyl-1-oxyl-piperidine, 2,2,6,6-substituted piperidine-1-oxyl free radical, or 2,2,5,5-substituted pyrrolidine-1-oxyl free radical derived from cyclic hydroxylamine. As a substituent, the alkyl group having less than four carbon atoms, such as methyl group or ethyl group. Specific nitroxide free radical compounds are not particularly limited, examples include, but are not limited to, 2,2,6,6-tetramethyl-1-piperidinyloxy free radicals, 2,2,6,6-tetraethyl-1-piperidinyloxy free radicals, 2,2,6,6-tetramethyl-4-oxo-1-piperidinyloxy free radicals, 2,2,5,5-tetramethyl-1-pyrrolidinyloxy free radicals, 1,1,3,3-tetramethyl-2-isoindolinyloxy free radical, and N,N-di-tert-butylaminoxyl free radicals. The nitroxide free radicals may also be replaced by using stable free radicals such as galvinoxyl free radicals. The polymerization inhibitor suitable for the resin composition of the present disclosure may also be derivatives in which hydrogen atoms or groups in the polymerization inhibitor are substituted with other atoms or groups. For instance, derivatives in which hydrogen atoms in the polymerization inhibitor are substituted by an amino group, a hydroxyl group, a carbonyl group or the like. Relative to 100 parts by weight of the thermosetting resin, the resin composition of the present disclosure may further include 0.001 to 20 parts by weight of the polymerization inhibitor, preferably 0.001 to 10 parts by weight of the polymerization inhibitor but the present disclosure is not limited thereto.

In one embodiment of the disclosure, the coloring agent may include, but is not limited to, dyes or pigments. Relative to 100 parts by weight of the thermosetting resin, the resin composition of the disclosure may further include 0.001 to 10 parts by weight of coloring agent, preferably 0.01 to 5 parts by weight of coloring agent, but the present disclosure is not limited thereto.

The type of the surfactant suitable for the resin composition of the disclosure is not particularly limited. The primary function of adding a surfactant is to ensure that the filler is uniformly dispersed in the resin composition. Relative to 100 parts by weight of the thermosetting resin, the resin composition of the disclosure may further include 0.001 to 10 parts by weight of the surfactant, preferably 0.01 to 5 parts by weight of the surfactant, but the present disclosure is not limited thereto.

In one embodiment of the disclosure, the primary function of adding a toughening agent is to improve the toughness of the resin composition. The toughening agent suitable for the disclosure may include, but is not limited to, carboxyl-terminated butadiene acrylonitrile rubber (CTBN), core-shell rubber, ethylene-propylene rubber, or a combination thereof. Relative to 100 parts by weight of the thermosetting resin, the resin composition of the disclosure may further include 1 to 20 parts by weight of the toughening agent, preferably 3 to 10 parts by weight of the toughening agent, but the present disclosure is not limited thereto.

The resin composition of the aforementioned embodiments may be made into various articles, for example, components in various electronic products, including but not limited to a prepreg, a resin film, a laminate, or a printed circuit board.

The resin composition of the disclosure may be made into a prepreg, which includes a reinforcement material and a layered structure disposed thereon. The layered structure is formed by heating the resin composition at a high temperature to a semi-cured state (B-stage). The baking temperature for making the prepreg may be between 120° C. and 180° C., preferably between 120° C. and 160° C. The reinforcement material may be any one of fiber material, woven fabric and non-woven fabric, and the woven fabric preferably includes glass fiber fabric. The types of the glass fiber fabric are not particularly limited and may be various glass fiber fabrics used for printed circuit boards, such as E-glass fabric, D-glass fabric, S-glass fabric, T-glass fabric, L-glass fabric, Q-glass fabric or QL-glass fabric (a mixed structure of Q glass and L glass). The type of the glass fibers includes yarns and rovings, in spread form or standard form, and the shape of terminal face may be round or flat. The non-woven fabric preferably includes liquid crystal polymer non-woven fabric, such as polyester non-woven fabric, polyurethane non-woven fabric and so on, but the present disclosure is not limited thereto. The woven fabric may also include liquid crystal polymer woven fabric, such as polyester woven fabric, polyurethane woven fabric and so on, but the present disclosure is not limited thereto. The reinforcement material may increase the mechanical strength of the prepreg. In one embodiment, the reinforcement material may be optionally pre-treated by a silane coupling agent. The prepreg is subsequently heated and cured (C-stage) to form an insulating layer.

The resin composition of the disclosure may be made into a resin film, which is obtained by heating and baking the resin composition to a semi-cured state (B-stage). The resin composition may be selectively coated on a liquid crystal polymer film, a polytetrafluoroethylene (PTFE) film, a polyethylene terephthalate (PET) film, a polyimide (PI) film, a copper foil (including, but not limited to, copper foil having a thickness of 28 mil and 1 ounce HVLP (hyper very low profile)) or a resin-coated copper (RCC), followed by heating and baking to form a semi-cured state so as to make the resin composition into the resin film.

The resin composition of the disclosure may be made into various laminates, which include at least two metal foils and at least one insulating layer, with the insulating layer disposed between the two metal foils, and the insulating layer may be formed by curing the resin composition under high temperature and high pressure (C-stage), the suitable curing temperature, for example, is between 190° C. and 250° C., preferably between 200° C. and 220° C.; the curing time is between 90 and 180 minutes, preferably between 120 and 150 minutes, the suitable pressing pressure is, for example, between 300 psi and 550 psi, preferably between 400 psi and 500 psi. The aforementioned insulating layer may be obtained by curing the aforementioned prepreg or resin film. The material of the aforementioned metal foil may be copper, aluminum, nickel, platinum, silver, gold, or alloys thereof, for example, copper foil (including, but not limited to, copper foil having a thickness of 28 mil and 1 ounce HVLP (hyper very low profile)). In a preferred embodiment, the laminate is a copper foil laminate.

The aforementioned laminate may be further processed through a circuit formation processing to form a printed circuit board. One method of manufacturing the printed circuit board of the present disclosure may be to use a double-sided copper-clad laminate with copper foil (e.g., product EM-891, available from Elite Electronic Material (KunShan) Co., Ltd.) with a thickness of 28 mil and having 1-ounce (oz) hyper very low profile (HVLP) copper foils may be used and subject to drilling and then electroplating, so as to form an electrical conduction between the upper layer copper foil and the bottom layer copper foil. Then, the upper layer copper foil and the bottom layer copper foil are etched to form an inner layer circuit. The inner layer circuit is then subjected to a brown oxidation and roughening treatment, thereby forming unevenstructure on the surface to increase roughness. Next, the copper foil, the aforementioned prepreg, the aforementioned inner layer circuit, the aforementioned prepreg, and the copper foil are stacked in sequence, and then a vacuum lamination apparatus is used to heat at a temperature between 190° C. and 245° C. for 90 to 240 minutes to cure the insulating layer material of the prepreg. Subsequently, on the outmost copper foil, a black oxidation, drilling, copper plating, and various circuit board processing processes known in the art are performed to obtain a printed circuit board.

The article made from the aforementioned resin composition includes a reinforcement material or a supporting material and a semi-cured or cured product obtained by heating and chemically cross-linking the resin composition.

The disclosure further provides an article, the article includes a resin cured product obtained by being completely cured (C-stage) the resin composition through a heating process. In the heating process, the suitable curing temperature may be between 150° C. and 250° C., preferably between 170° C. and 220° C., with a curing time of 60 to 240 minutes, preferably 60 to 180 minutes.

The shape of the resin cured product is not particularly limited and may be in the form of layers, blocks, particles, etc. The method for preparing the resin cured product is not particularly limited and may involve placing the resin composition in a mold with a specific shape and heating until completely cured, the mold with a specific shape may include, but is not limited to, a laminate or printed circuit board with grooves, various holes of a printed circuit board, or open areas of a circuit of a printed circuit board; it may also be coated on a support material and heated until completely cured.

For example, the aforementioned article includes only the resin cured product obtained by curing the resin composition. For instance, the article includes both the resin cured product obtained by curing the resin composition and a support material. The support material may include, but is not limited to, a liquid crystal polymer film, a polytetrafluoroethylene (PTFE) film, a polyethylene terephthalate (PET) film, a polyimide (PI) film, or metal foil.

The present disclosure also provides an application of the aforementioned resin composition in a resin plugging process of a printed circuit board (PCB) (resin filling). The resin fillingprocess includes, but is not limited to, a hole plugging process of a printed circuit board, a groove filling process of a printed circuit board, and a printed circuit board circuit fillingprocess. The present disclosure further provides an application of the aforementioned resin composition in a hole plugging process of a printed circuit board (hole plugging). For instance, in the manufacturing process of a printed circuit board, the laminate is first drilled once, and, as required by the process, selectively electroplated, then a hole plugging process is performed. For instance, after drilling, electroplating may be carried out first to form electrical conduction between the upper layer foil and the bottom layer copper foil, followed by the hole plugging process. Alternatively, the laminate may be subject to hole plugging after drilling, and then the laminate subjected to hole plugging is subjected to secondary drilling, wherein the hole diameter of secondary drilling is usually smaller than that of the first drilling, and copper is electroplated onto the wall of the second drilling hole. The resin composition of the present disclosure is particularly suitable for the hole plugging process of printed circuit boards, wherein the resin composition is plugged into the holes and completely cured, followed by subsequent various circuit board processing processes known in the art. Specifically, at least one hole of the printed circuit board is filled with the resin cured product of the resin composition, followed by subsequent various circuit board processing processes known in the art.

The present disclosure also provides an application of the aforementioned resin composition in a groove filling process of a printed circuit board (groove filling). For instance, in the manufacturing process of a printed circuit board, a groove is formed in a non-wiring area of the laminate, and the groove is filled with resin varnish, cured, and planarized, followed by subsequent various circuit board processing processes known in the art. Specifically, at least one groove of the printed circuit board is filled with the resin cured product of the resin composition, followed by subsequent various circuit board processing processes known in the art. In this case, the groove wall may be either an electroplated groove or a non-electroplated groove.

The present disclosure further provides an application of the aforementioned resin composition in a circuit filling process of a printed circuit board (circuit filling). For instance, in the manufacturing process of a printed circuit board, after forming inner layer circuit by circuit processing of a laminate, and optionally performing a circuit filling process according to the copper thickness of the inner layer circuit. The resin composition of the present disclosure is particularly suitable for the circuit filling process of the printed circuit board, and the resin composition is filled into the open area (i.e., an area without a circuit) of the circuit and completely cured, followed by subsequent various circuit board processing processes known in the art. Specifically, at least one circuit open area of the printed circuit board is covered with the resin cured product of the resin composition, followed by subsequent various circuit board processing processes known in the art.

The resin composition of the present disclosure is used in the filling process of the printed circuit board, and the printed circuit board containing the resin cured product prepared preferably exhibits one or more of the following properties:
a solder floating crack rate of the printed circuit board as measured by reference to IPC-TM-650 2.4.13.1 of 0%;
an impedance amplitude of a hole region of the printed circuit board as measured by reference to a network analyzer equipped with a time-domain reflectometer (TDR) module of less than or equal to 10%, for example, the impedance amplitude of the hole region of less than 5%, or, for example, between 5% and 10%;
a continuous varnish scraping time of greater than or equal to 15 minutes, for example, between 15 minutes and 1 hour, or, for example, a continuous varnish scraping time of greater than 1 hour during the resin filling process of the printed circuit board.

Preferably, the resin composition disclosed in the present disclosure or any article containing the resin cured product made therefrom preferably exhibits one or more of the following properties:
a varnish shelf life of the resin composition of greater than 90 days;
an organic volatile matters of the resin composition as measured by reference to IPC-TM-650 2.4.24.6 of less than or equal to 0.50%, for example, between 0.10% and 0.50%;
a dissipation factor at a frequency of 10 GHz as measured by reference to JIS C2565 of less than or equal to 0.0041, for example, between 0.0035 and 0.0041;
a copper foil peeling strength as measured by reference to IPC-TM-650 2.4.8 of greater than or equal to 5.9 lb/in, for example, between 4.3 lb/in and 5.9 lb/in;
a Z-axis percent of thermal expansion as measured by reference to IPC-TM-650 2.4.24.5 of less than or equal to 1.70%, for example, between 1.00% and 1.70%;
a water absorption ratio as measured by reference to IPC-TM-650 2.6.2.1 and IPC-TM-650 2.6.16.1 of less than or equal to 0.30%, for example, between 0.21% and 0.30%; and
a shear viscosity variation rate of the resin composition as measured by reference to GB/T 2794-2022 7.3 of 9 to 56%.

By optimizing the dissipation factor, the organic volatile matters, and the shear viscosity variation rate of the resin composition, the solder floating crack rate, impedance stability, and varnish scraping stability of the printed circuit board containing the resin cured product used in the resin filling process of the printed circuit board may be further improved.

Various raw materials below are used to prepare the resin compositions of Examples and Comparative Examples of the present disclosure according to the amount listed in Table 1 to Table 9, and further made into testing samples or articles.

The chemical materials used in Examples and Comparative Examples of the present disclosure are described as follows:

Ricon 131MA5: maleic anhydride-adducted polybutadiene, available from Cray Valley SA.

Ricon 130MA8: maleic anhydride-adducted polybutadiene, available from Cray Valley SA.

Ricon 130MA13: maleic anhydride-adducted polybutadiene, available from Cray Valley SA.

Ricon 131MA10: maleic anhydride-adducted polybutadiene, available from Cray Valley SA.

Ricon 156MA17: maleic anhydride-adducted polybutadiene, available from Cray Valley SA.

Ricon 184MA6: maleic anhydride-adducted styrene-butadiene copolymer, available from Cray Valley SA.

XIRAN-EF80: styrene-maleic anhydride copolymer, available from Aurorium.

Ricon 130: polybutadiene, available from Cray Valley SA.

G1726: hydrogenated styrene-butadiene-styrene block copolymer, available from Kraton Corporation.

SBS-A: styrene-butadiene block copolymer, specifically styrene-butadiene-styrene triblock copolymer, available from Nippon Soda Co., Ltd.

SR833S: tricyclodecane dimethanol diacrylate, structure as shown below, available from Sartomer, and the glass transition temperature of its cured product is about 180° C.

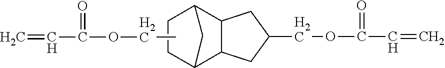

SR368NS: tris(2-hydroxyethyl) isocyanurate triacrylate, structure as shown below, available from Sartomer, and the glass transition temperature of its cured product is about 272° C.

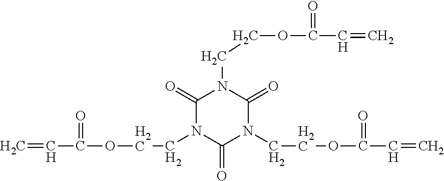 [SMILES: C=CC(=O)OCCn1c(=O)n(CCOC(=O)C=C)c(=O)n(CCOC(=O)C=C)c1=O]

The oligomer of SR833S: the oligomer of tricyclodecane dimethanol diacrylate obtained by polymerizing tricyclodecane dimethanol diacrylate, having a weight-average molecular weight of less than 2000, and the glass transition temperature of its cured product is about 180° C.

SR295 NS: pentaerythritol tetraacrylate, structure as shown below, available from Sartomer, and the glass transition temperature of its cured product is about 103° C.

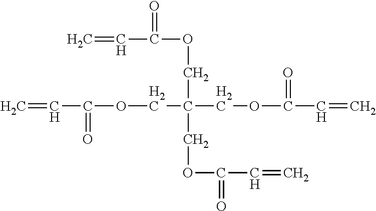 [SMILES: C=CC(=O)OCC(COC(=O)C=C)(COC(=O)C=C)COC(=O)C=C]

SR399 NS: dipentaerythritol pentaacrylate, structure as shown below, available from Sartomer, and the glass transition temperature of its cured product is about 90° C.

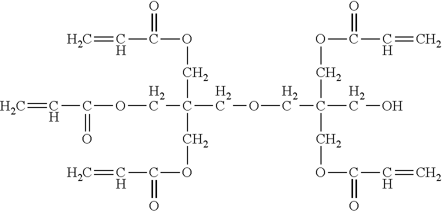 [SMILES: C=CC(=O)OCC(CO)(COCC(COC(=O)C=C)(COC(=O)C=C)COC(=O)C=C)COC(=O)C=C]

DPHA: dipentaerythritol hexaacrylate, structure as shown below, available from Sartomer, and the glass transition temperature of its cured product is about 90° C.

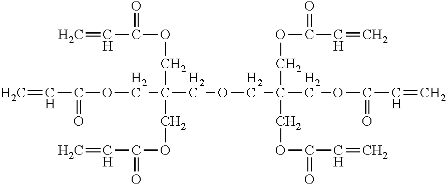 [SMILES: C=CC(=O)OCC(COCC(COC(=O)C=C)(COC(=O)C=C)COC(=O)C=C)(COC(=O)C=C)COC(=O)C=C]

Maleimide as shown in Formula (1): Commercially available, wherein p₂ is a value of 1 to 10.

Maleimide as shown in Formula (2): Commercially available, wherein p₃ is a value of 1 to 10.

Maleimide as shown in Formula (3): Commercially available, wherein all R1 are methyl, all m1 are 2, n1 is 0, and p₁ is a value of 0.5 to 20.

BMI-5100: 3,3′-dimethyl-5,5′-diethyl-4,4′-diphenylmethane bismaleimide, structure as shown below, available from Daiwakasei Industry Co., Ltd.

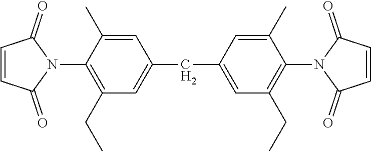 [SMILES: CCc1cc(Cc2cc(C)c(N3C(=O)C=CC3=O)c(CC)c2)cc(C)c1N1C(=O)C=CC1=O]

BMI-2300: polyphenylmethane maleimide, structure as shown below, wherein p₄ is a value of 1 to 10, available from Daiwakasei Industry Co., Ltd.

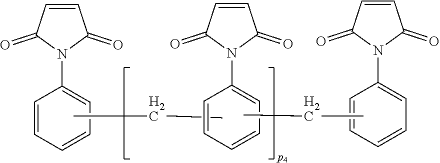

BMI-4000: bisphenol A diphenyl ether bismaleimide, structure as shown below, available from Daiwakasei Industry Co., Ltd.

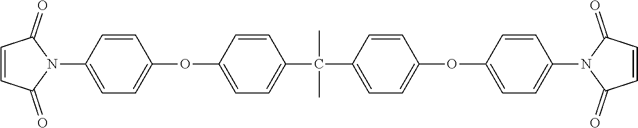 [SMILES: CC(C)(c1ccc(Oc2ccc(N3C(=O)C=CC3=O)cc2)cc1)c1ccc(Oc2ccc(N3C(=O)C=CC3=O)cc2)cc1]

BMI-1000:4,4′-diphenylmethane bismaleimide, structure as shown below, available from Daiwakasei Industry Co., Ltd.

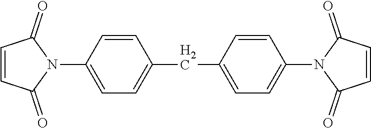 [SMILES: O=C1C=CC(=O)N1c1ccc(Cc2ccc(N3C(=O)C=CC3=O)cc2)cc1]

BMI-1500: maleimide with an aliphatic structure containing 10 to 50 carbon atoms, structure as shown below, wherein p₅ is a value of 1 to 10, available from Designer Molecules Inc.

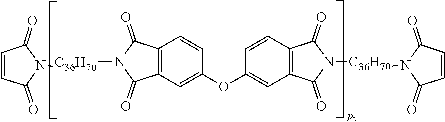

BMI-3000: maleimide with an aliphatic structure containing 10 to 50 carbon atoms, structure as shown below, wherein p₆ is a value of 1 to 10, available from Designer Molecules Inc.

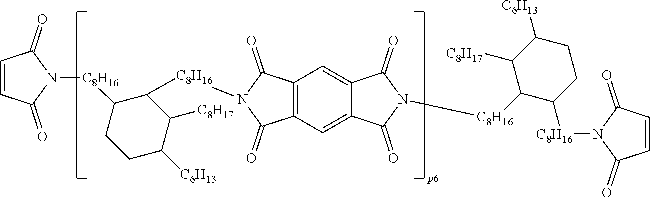

BMI-1700: maleimide with an aliphatic structure containing 10 to 50 carbon atoms, structure as shown below, wherein p₇ is a value of 1 to 10, available from Designer Molecules Inc.

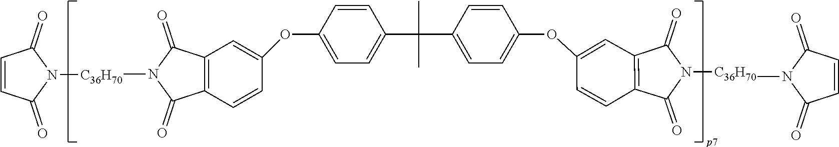

SA9000: (meth)acryloyl group-containing polyphenylene ether resin, available from SABIC.

OPE-2st 2200: vinylbenzyl group-containing polyphenylene ether resin, available from Mitsubishi Gas Chemical Co., Inc.

OPE-2st 1200: vinylbenzyl group-containing polyphenylene ether resin, available from Mitsubishi Gas Chemical Co., Inc.

B-461: organic silicone resin, available from Guangdong Zillbon Chemical Co., Ltd.

X-22-161A: amino-modified organic silicone resin, available from Shin-Etsu Chemical Co., Ltd.

BY-16-853B: amino-modified organic silicone resin, available from Toray-Dow Corning Co., Ltd.

XF42-C5379: amino-modified organic silicone resin, available from Momentive Performance Materials Japan LLC.

BA-230S: bisphenol A cyanate ester, available from Arxada AG.

HTL-300: vinyl-functionalized cyanate ester, available from Arxada AG.

CE-320: cyanate ester resin, available from Arxada AG.

HP 6000: naphthyl ether epoxy resin, available from DIC Co., Ltd.

HP 7200: dicyclopentadiene epoxy resin, available from DIC Co., Ltd.

YX7700: phenol aralkyl-type epoxy resin, available from Mitsubishi Chemical Co., Ltd.

YD-128: bisphenol A epoxy resin, available from Nippon Steel Chemical Co., Ltd.

LZ-82919: bisphenol A benzoxazine resin, available from Huntsman.

KZH-5031: vinyl-modified benzoxazine resin, available from Kolon Industries, Inc. (Korea).

PF-3500: bis(aminodiphenyl) ether benzoxazine resin, available from Changchun Plastics Co., Ltd.

HPC-8000-65T: active polyester resin, available from DIC Co., Ltd.

HPC-8150-62T: active polyester resin, available from DIC Co., Ltd.

YP-50: phenoxy resin, available from Nippon Steel Chemical Co., Ltd.

DCP: dicumyl peroxide, available from NOF Co., Ltd.

P₁: surface-porous treated solid spherical silica, D100 particle size 5 μm, specific surface area 200 m²/g, commercially available.

P₂: surface-porous treated solid spherical silica, D100 particle size 10 μm, specific surface area 130 m²/g, commercially available.

P₃: surface-porous treated solid spherical silica, D100 particle size 15.9 μm, specific surface area 103 m²/g, commercially available.

P₄: surface-porous treated solid spherical silica, D100 particle size 20 μm, specific surface area 40 m²/g, commercially available.

Nano silica: YA050C-MJE, average particle size 0.050 μm, specific surface area 61.8 m²/g, available from Admatechs, Japan.

Hollow silica: available from Suzhou Ginet New Material Technology Co., Ltd.

Chemically synthesized spherical silica (spherical SiO₂ (synthesis method)): median particle size (D50) of about 1.5±0.5 μm, prepared by a microemulsion method and surface-treated with a silane coupling agent, available from Suzhou Ginet New Material Technology Co., Ltd.

The components (in parts by weight) and the test results of the resin components for the examples and comparative examples of the present disclosure are shown in Tables 1 to 9:

TABLE 1
Components (in parts by weight) and test results of the resin compositions for Examples E1 to E5.

| Components | | E1 | E2 | E3 | E4 | E5 |
|---|---|---|---|---|---|---|
| Ployolefin | Ricon 131MA5 | — | — | — | 10 | 5 |
| | Ricon 130MA8 | 40 | 40 | — | 30 | — |
| | Ricon 130MA13 | — | — | 30 | — | 30 |
| | Ricon 131MA10 | — | — | 10 | — | — |
| | Ricon 156MA17 | — | 5 | — | 5 | — |
| | Ricon 184MA6 | 10 | 5 | 5 | — | 10 |
| | XIRAN-EF80 | — | — | — | — | — |
| | Ricon 130 | 10 | 5 | 8 | 5 | 5 |
| | G1726 | — | — | — | — | — |
| | SBS-A | — | — | — | — | — |
| Acrylate ester | SR833S | 25 | 30 | 20 | 30 | 40 |
| compound | SR368NS | 5 | — | — | — | — |
| | Oligomer of SR833S | — | — | 10 | 5 | 4 |
| | SR295 NS | — | — | — | — | — |
| | SR399 NS | — | — | — | — | — |
| | DPHA | — | — | — | — | — |
| Maleimide resin | Maleimide as shown | 7 | 8 | 5 | 6 | 5 |
| | in Formula (1) | | | | | |
| | Maleimide as shown | — | 2 | — | 2 | — |
| | in Formula (2) | | | | | |
| | Maleimide as shown | 2 | — | 2 | 2 | — |
| | in Formula (3) | | | | | |
| | BMI-5100 | — | — | — | — | — |
| | BMI-2300 | — | — | — | — | — |
| | BMI-4000 | — | — | 2 | — | — |
| | BMI-1000 | — | — | 2 | — | — |
| | BMI-1500 | — | — | — | — | — |
| | BMI-3000 | — | — | — | — | — |
| | BMI-1700 | — | — | — | — | — |
| Polyphenylene ether | SA9000 | — | — | — | — | — |
| resin | OPE-2ST 2200 | — | — | — | 2 | — |
| | OPE-2ST 1200 | — | 4 | 5 | 2 | — |
| Organic silicone | B-461 | 1 | — | — | — | 1 |
| resin | X-22-161A | — | 1 | — | — | — |
| | BY-16-853B | — | — | 1 | — | — |
| | XF42-C5379 | — | — | — | 1 | — |
| Cyanate ester | BA-230S | — | — | — | — | — |
| resin | HTL-300 | — | — | — | — | — |
| | CE-320 | — | — | — | — | — |
| Epoxy resin | HP 6000 | — | — | — | — | — |
| | HP 7200 | — | — | — | — | — |
| | YX7700 | — | — | — | — | — |
| Benzoxazine | LZ-8290 | — | — | — | — | — |
| resin | KZH-5031 | — | — | — | — | — |
| | PF-3500 | — | — | — | — | — |
| Active ester | HPC-8000 | — | — | — | — | — |
| | HPC-8150 | — | — | — | — | — |
| Phenoxy resin | YP-50 | — | — | — | — | — |
| Inorganic | P2 | 10 | 10 | 10 | 8 | 15 |
| filler | Hollow silica | — | — | — | 2 | — |
| | Spherical SiO₂ | 150 | 200 | 180 | 180 | 180 |
| | (synthesis method) | | | | | |
| Initiator | DCP | 2.0 | 3.0 | 3.0 | 3.0 | 3.0 |
| Solvent | / | Not | Not | Not | Not | Not |
| | | added | added | added | added | added |
| Organic volatile | % | 0.2 | 0.6 | 0.5 | 0.8 | 1.3 |
| matters | | | | | | |
| Shear viscosity | % | 18 | 12 | 21 | 15 | 30 |
| variation rate | | | | | | |
| Dissipation factor | / | 0.0040 | 0.0040 | 0.0042 | 0.0044 | 0.0048 |

| Properties | Unit | E1 | E2 | E3 | E4 | E5 |
|---|---|---|---|---|---|---|
| Impedance stability | / | A | A | A | A | A |
| Solder floating crack | % | 0 | 0 | 0 | 0 | 0 |
| rate | | | | | | |
| Varnish scraping | / | A | A | A | A | A |
| stability | | | | | | |

TABLE 2
Components (in parts by weight) and test results
of the resin compositions for Examples E6 to E10.

| Components | | E6 | E7 | E8 | E9 | E10 |
|---|---|---|---|---|---|---|
| Ployolefin | Ricon 131MA5 | — | — | — | 10 | — |
| | Ricon 130MA8 | — | 30 | — | 20 | — |
| | Ricon 130MA13 | — | — | — | — | 20 |
| | Ricon 131MA10 | 25 | — | 30 | — | — |
| | Ricon 156MA17 | — | — | 5 | 5 | — |
| | Ricon 184MA6 | 13 | 15 | — | 5 | — |
| | XIRAN-EF80 | — | — | — | — | 5 |
| | Ricon 130 | 10 | 5 | 5 | 4 | — |
| | G1726 | — | — | — | 1 | — |
| | SBS-A | — | — | — | — | 1 |
| Acrylate ester | SR833S | 46 | 20 | 40 | 20 | 45 |
| compound | SR368NS | — | — | — | 5 | — |
| | Oligomer of SR833S | — | — | 16 | — | — |
| | SR295 NS | — | 5 | — | — | — |
| | SR399 NS | — | 5 | — | — | — |
| | DPHA | — | — | — | 5 | — |
| Maleimide | Maleimide as shown in | 5 | — | — | 5 | 5 |
| resin | Formula (1) | | | | | |
| | Maleimide as shown in | — | 5 | — | — | — |
| | Formula (2) | | | | | |
| | Maleimide as shown in | — | 5 | — | — | — |
| | Formula (3) | | | | | |
| | BMI-5100 | — | — | — | 2 | — |
| | BMI-2300 | — | — | 3 | — | — |
| | BMI-4000 | — | — | — | — | — |
| | BMI-1000 | — | — | — | — | — |
| | BMI-1500 | — | — | — | 2 | — |
| | BMI-3000 | — | — | — | — | 2 |
| | BMI-1700 | — | — | — | — | 2 |
| Polyphenylene | SA9000 | — | — | — | 2 | — |
| ether resin | OPE-2ST 2200 | — | 5 | — | — | — |
| | OPE-2ST 1200 | — | 4 | — | — | — |
| Organic silicone | B-461 | — | 1 | 1 | — | 4 |
| resin | X-22-161A | 1 | — | — | — | — |
| | BY-16-853B | — | — | — | 2 | — |
| | XF42-C5379 | — | — | — | — | — |
| Cyanate ester | BA-230S | — | — | — | 2 | — |
| resin | HTL-300 | — | — | — | — | 2 |
| | CE-320 | — | — | — | 2 | — |
| Epoxy resin | HP 6000 | — | — | — | — | 2 |
| | HP 7200 | — | — | — | 2 | — |
| | YX7700 | — | — | — | — | 4 |
| Benzoxazine | LZ-8290 | — | — | — | 2 | — |
| resin | KZH-5031 | — | — | — | — | 2 |
| | PF-3500 | — | — | — | 2 | — |
| Active ester | HPC-8000 | — | — | — | — | 4 |
| | HPC-8150 | — | — | — | 2 | — |
| Phenoxy resin | YP-50 | — | — | — | — | 2 |
| Inorganic filler | P2 | 20 | 15 | 10 | 5 | 10 |
| | Hollow silica | — | — | — | — | — |
| | Spherical SiO₂ | 200 | 120 | 150 | 230 | 90 |
| | (synthesis method) | | | | | |
| Initiator | DCP | 3.0 | 3.0 | 2.0 | 10.0 | 1.0 |
| Solvent | / | Not | Not | Not | Not | Not |
| | | added | added | added | added | added |
| Organic volatile | % | 1.6 | 0.3 | 1.4 | 0.3 | 1.7 |
| matters | | | | | | |
| Shear viscosity | % | 41 | 24 | 24 | 47 | 27 |
| variation rate | | | | | | |
| Dissipation factor | / | 0.0047 | 0.0050 | 0.0056 | 0.0063 | 0.0070 |

| Properties | Unit | E6 | E7 | E8 | E9 | E10 |
|---|---|---|---|---|---|---|
| Impedance | / | A | B | B | B | B |
| stability | | | | | | |
| Solder floating | % | 0 | 0 | 0 | 0 | 0 |
| crack rate | | | | | | |
| Varnish scraping | / | A | A | A | B | A |
| stability | | | | | | |

TABLE 3
Components (in parts by weight) and test results of the resin compositions for Comparative Examples C1 to C7.

| Components | | C1 | C2 | C3 | C4 | C5 | C6 | C7 |
|---|---|---|---|---|---|---|---|---|
| Ployolefin | Ricon 131MA5 | — | — | — | — | — | — | 40 |
| | Ricon 130MA8 | — | — | — | — | — | 40 | — |
| | Ricon 130MA13 | — | — | — | — | 36 | — | — |
| | Ricon 131MA10 | — | — | — | — | — | — | — |
| | Ricon 156MA17 | — | — | — | — | — | — | 5 |
| | Ricon 184MA6 | — | — | — | — | 10 | 5 | — |
| | XIRAN-EF80 | — | — | — | — | — | — | — |
| | Ricon 130 | — | — | — | — | 8 | 5 | 5 |
| | G1726 | — | — | — | — | — | — | — |
| | SBS-A | — | — | — | — | — | — | — |
| Acrylate | SR833S | 25 | 25 | 50 | 55 | 20 | 20 | 30 |
| ester | SR368NS | — | — | — | — | 10 | — | — |
| compound | Oligomer of | — | — | 10 | 5 | — | 10 | 5 |
| | SR833S | | | | | | | |
| | SR295 NS | — | — | — | — | — | — | — |
| | SR399 NS | — | — | — | — | — | — | — |
| | DPHA | — | — | — | — | — | — | — |
| Maleimide | Maleimide | — | — | — | — | 5 | — | 8 |
| resin | as shown in | | | | | | | |
| | Formula (1) | | | | | | | |
| | Maleimide | — | — | — | 10 | — | 9 | — |
| | as shown in | | | | | | | |
| | Formula (2) | | | | | | | |
| | Maleimide | — | — | — | — | 5 | — | — |
| | as shown in | | | | | | | |
| | Formula (3) | | | | | | | |
| | BMI-5100 | — | — | — | — | — | 5 | 2 |
| | BMI-2300 | 5 | — | — | — | — | — | — |
| | BMI-4000 | — | — | 5 | — | — | — | — |
| | BMI-1000 | — | 5 | — | — | — | — | — |
| | BMI-1500 | — | — | — | — | — | — | — |
| | BMI-3000 | — | — | — | — | — | — | — |
| | BMI-1700 | — | — | — | — | — | — | — |
| Polyphenylene | SA9000 | — | — | — | — | — | 5 | — |
| ether resin | OPE-2ST 2200 | — | — | — | — | — | — | 2 |
| | OPE-2ST 1200 | — | — | — | — | 5 | — | 2 |
| Organic | B-461 | 2 | — | 2 | 1 | — | — | — |
| silicone | X-22-161A | — | 2 | — | — | — | 1 | — |
| resin | BY-16-853B | — | — | — | — | 1 | — | — |
| | XF42-C5379 | — | — | — | — | — | — | 1 |
| Cyanate | BA-230S | — | 20 | — | — | — | — | — |
| ester resin | HTL-300 | — | — | 10 | — | — | — | — |
| | CE-320 | 20 | — | — | 10 | — | — | — |
| Epoxy resin | HP 6000 | — | 30 | — | — | — | — | — |
| | HP 7200 | — | 8 | 10 | — | — | — | — |
| | YX7700 | 38 | — | — | 10 | — | — | — |
| Benzoxazine | LZ-8290 | — | — | — | — | — | — | — |
| resin | KZH-5031 | — | — | — | 3 | — | — | — |
| | PF-3500 | — | — | 3 | — | — | — | — |
| Active ester | HPC-8000 | 10 | — | — | 3 | — | — | — |
| | HPC-8150 | — | 10 | — | — | — | — | — |
| phenoxy resin | YP-50 | — | | 10 | 3 | — | — | — |
| Inorganic | P2 | 5 | 2 | 5 | 2 | 1 | 4 | 2 |
| filler | Hollow silica | — | — | — | — | — | — | — |
| | Spherical SiO₂ | 100 | 100 | 100 | 100 | 180 | 180 | 180 |
| | (synthesis method) | | | | | | | |
| Initiator | DCP | 5.0 | 5.0 | 3.0 | 3.0 | 3.0 | 3.0 | 3.0 |
| Solvent | Toluene | Not | Not | Not | Not | 20 | 20 | Not |
| | | added | added | added | added | | | added |
| Organic | % | 0.3 | 0.3 | 2.3 | 2.5 | 7.5 | 7.1 | 0.7 |
| volatile | | | | | | | | |
| matters | | | | | | | | |
| Shear | % | 53 | 98 | 50 | 92 | 71 | 38 | 95 |
| viscosity | | | | | | | | |
| variation rate | | | | | | | | |
| Dissipation | / | 0.0094 | 0.0097 | 0.0092 | 0.0089 | 0.0045 | 0.0047 | 0.0045 |
| factor | | | | | | | | |
| Properties | Unit | C1 | C2 | C3 | C4 | C5 | C6 | C7 |
| Impedance | / | C | C | C | C | A | A | A |
| stability | | | | | | | | |
| Solder | % | 53 | 50 | 35 | 40 | 73 | 68 | 0 |
| floating | | | | | | | | |
| crack rate | | | | | | | | |
| Varnish | / | B | C | B | C | C | A | C |
| scraping | | | | | | | | |
| stability | | | | | | | | |

TABLE 4
Components (in parts by weight) and test results of
the resin compositions for Examples E11 to E15.

| Components | | E11 | E12 | E13 | E14 | E15 |
|---|---|---|---|---|---|---|
| Maleic anhydride- | Ricon 131MA5 | — | — | — | — | — |
| modified polyolefin | Ricon 130MA8 | 100 | 100 | 100 | 100 | 100 |
| | Ricon 130MA13 | — | — | — | — | — |
| | Ricon 131MA10 | — | — | — | — | — |
| | Ricon 156MA17 | — | — | — | — | — |
| | Ricon 184MA6 | — | — | — | — | — |
| | XIRAN-EF80 | — | — | — | — | — |
| Multifunctional | SR833S | 60 | 60 | 30 | 90 | 60 |
| (meth)acrylate | SR368NS | — | — | — | — | — |
| monomer and/or its | Oligomer of | — | — | — | — | — |
| oligomer | SR833S | | | | | |
| | SR295 NS | — | — | — | — | — |
| | SR399 NS | — | — | — | — | — |
| | DPHA | — | — | — | — | — |
| Surface-porous | P1 | — | — | — | — | — |
| silica | P2 | — | — | — | — | — |
| | P3 | 10 | 30 | 20 | 20 | 30 |
| | P4 | — | — | — | — | — |
| Spherical SiO₂ | | 270 | 270 | 270 | 270 | 150 |
| (synthesis method) | | | | | | |
| Nano silica | | — | — | — | — | — |
| Hollow silica | | — | — | — | — | — |
| Initiator | DCP | 6.0 | 6.0 | 6.0 | 6.0 | 6.0 |
| Properties | Unit | E11 | E12 | E13 | E14 | E15 |
| Varnish storage life | Day(days) | >90 | >90 | >90 | >90 | >90 |
| Organic volatile | % | 0.4 | 0.3 | 0.2 | 0.5 | 0.4 |
| matters | | | | | | |
| Dissipation factor | / | 0.0038 | 0.0040 | 0.0038 | 0.0041 | 0.0040 |
| Z-axis coefficient of | % | 1.3 | 1.1 | 1.4 | 1.1 | 1.7 |
| thermal expansion | | | | | | |
| Copper foil peeling | lb/in | 4.3 | 4.6 | 4.4 | 4.8 | 5.9 |
| strength | | | | | | |
| Water absorption | % | 0.24 | 0.26 | 0.24 | 0.30 | 0.21 |
| ratio | | | | | | |
| Shear viscosity | % | 35 | 38 | 38 | 12 | 53 |
| variation rate | | | | | | |

TABLE 5
Components (in parts by weight) and test results of
the resin compositions for Examples E16 to E20.

| Components | | E16 | E17 | E18 | E19 | E20 |
|---|---|---|---|---|---|---|
| Maleic anhydride- | Ricon 131MA5 | 100 | — | — | — | — |
| modified polyolefin | Ricon 130MA8 | — | — | — | — | 100 |
| | Ricon 130MA13 | — | 100 | — | — | — |
| | Ricon 131MA10 | — | — | — | — | — |
| | Ricon 156MA17 | — | — | 100 | — | — |
| | Ricon 184MA6 | — | — | — | 100 | — |
| | XIRAN-EF80 | — | — | — | — | — |
| Multifunctional | SR833S | — | — | — | — | 60 |
| (meth)acrylate | SR368NS | 30 | 90 | — | — | — |
| monomer and/or its | Oligomer of | — | — | 60 | 90 | — |
| oligomer | SR833S | | | | | |
| | SR295 NS | — | — | — | — | — |
| | SR399 NS | — | — | — | — | — |
| | DPHA | — | — | — | — | — |
| Surface-porous | P1 | 10 | 30 | — | — | 20 |
| silica | P2 | — | — | 30 | 10 | — |
| | P3 | — | — | — | — | — |
| | P4 | — | — | — | — | — |
| Spherical SiO₂ | | 200 | 300 | 250 | 350 | 270 |
| (synthesis method) | | | | | | |
| Nano silica | | — | — | — | — | — |
| Hollow silica | | — | — | — | — | — |
| Initiator | DCP | 6.0 | 6.0 | 6.0 | 6.0 | 6.0 |
| Properties | Unit | E16 | E17 | E18 | E19 | E20 |
| Varnish storage life | Day(days) | >90 | >90 | >90 | >90 | >90 |
| Organic volatile | % | 0.1 | 0.3 | 0.1 | 0.3 | 0.3 |
| matters | | | | | | |
| Dissipation factor | / | 0.0040 | 0.0038 | 0.0037 | 0.0035 | 0.0039 |
| Z-axis coefficient of | % | 1.2 | 1.0 | 1.3 | 1.0 | 1.2 |
| thermal expansion | | | | | | |
| Copper foil peeling | lb/in | 4.6 | 5.2 | 4.8 | 5.1 | 4.8 |
| strength | | | | | | |
| Water absorption | % | 0.25 | 0.26 | 0.25 | 0.27 | 0.25 |
| ratio | | | | | | |
| Shear viscosity | % | 30 | 21 | 41 | 18 | 15 |
| variation rate | | | | | | |

TABLE 6
Components (in parts by weight) and test results of
the resin compositions for Examples E21 to E25.

| Components | | E21 | E22 | E23 | E24 | E25 |
|---|---|---|---|---|---|---|
| Maleic anhydride- | Ricon 131MA5 | — | — | — | — | — |
| modified polyolefin | Ricon 130MA8 | 100 | 100 | 100 | 100 | 100 |
| | Ricon 130MA13 | — | — | — | — | — |
| | Ricon 131MA10 | — | — | — | — | — |
| | Ricon 156MA17 | — | — | — | — | — |
| | Ricon 184MA6 | — | — | — | — | — |
| | XIRAN-EF80 | — | — | — | — | — |
| Multifunctional | SR833S | 60 | 60 | 60 | — | — |
| (meth)acrylate | SR368NS | — | — | — | 60 | — |
| monomer and/or its | Oligomer of | — | — | — | — | 60 |
| oligomer | SR833S | | | | | |
| | SR295 NS | — | — | — | — | — |
| | SR399 NS | — | — | — | — | — |
| | DPHA | — | — | — | — | — |
| Surface-porous | P1 | — | — | — | — | — |
| silica | P2 | 20 | — | — | — | — |
| | P3 | — | 20 | — | 20 | 20 |
| | P4 | — | — | 20 | — | — |
| Spherical SiO₂ | | 270 | 270 | 270 | 270 | 270 |
| (synthesis method) | | | | | | |
| Nano silica | | — | — | — | — | — |
| Hollow silica | | — | — | — | — | — |
| Initiator | DCP | 6.0 | 6.0 | 6.0 | 6.0 | 6.0 |
| Properties | Unit | E21 | E22 | E23 | E24 | E25 |
| Varnish storage life | Day(days) | >90 | >90 | >90 | >90 | >90 |
| Organic volatile | % | 0.3 | 0.3 | 0.3 | 0.2 | 0.2 |
| matters | | | | | | |
| Dissipation factor | / | 0.0039 | 0.0039 | 0.0039 | 0.0038 | 0.0038 |
| Z-axis coefficient of | % | 1.2 | 1.3 | 1.2 | 1.0 | 1.4 |
| thermal expansion | | | | | | |
| Copper foil peeling | lb/in | 4.7 | 4.6 | 4.4 | 4.7 | 4.8 |
| strength | | | | | | |
| Water absorption | % | 0.25 | 0.24 | 0.25 | 0.24 | 0.23 |
| ratio | | | | | | |
| Shear viscosity | % | 30 | 24 | 56 | 32 | 41 |
| variation rate | | | | | | |

TABLE 7
Components (in parts by weight) and test results of
the resin compositions for Examples E26 to E30.

| Components | | E26 | E27 | E28 | E29 | E30 |
|---|---|---|---|---|---|---|
| Maleic anhydride- | Ricon 131MA5 | — | — | — | — | — |
| modified polyolefin | Ricon 130MA8 | 100 | 100 | 100 | 70 | 80 |
| | Ricon 130MA13 | — | — | — | — | — |
| | Ricon 131MA10 | — | — | — | — | — |
| | Ricon 156MA17 | — | — | — | — | 10 |
| | Ricon 184MA6 | — | — | — | 30 | — |
| | XIRAN-EF80 | — | — | — | — | 10 |
| Multifunctional | SR833S | — | — | — | 20 | 70 |
| (meth)acrylate | SR368NS | — | — | — | 20 | — |
| monomer and/or its | Oligomer of | — | — | — | — | — |
| oligomer | SR833S | | | | | |
| | SR295 NS | 60 | — | — | — | — |
| | SR399 NS | — | 60 | — | — | — |
| | DPHA | — | — | 60 | — | — |
| Surface-porous | P1 | — | — | — | 5 | 10 |
| silica | P2 | — | — | — | 5 | — |
| | P3 | 20 | 20 | 20 | 5 | 5 |
| | P4 | — | — | — | — | — |
| Spherical SiO₂ | | 270 | 270 | 270 | 150 | 350 |
| (synthesis method) | | | | | | |
| Nano silica | | — | — | — | — | — |
| Hollow silica | | — | — | — | — | — |
| Initiator | DCP | 6.0 | 6.0 | 6.0 | 1.0 | 10.0 |
| Properties | Unit | E26 | E27 | E28 | E29 | E30 |
| Varnish storage life | Day(days) | >90 | >90 | >90 | >90 | >90 |
| Organic volatile | % | 0.2 | 0.2 | 0.2 | 0.2 | 0.3 |
| matters | | | | | | |
| Dissipation factor | / | 0.0040 | 0.0040 | 0.0040 | 0.0039 | 0.0037 |
| Z-axis coefficient of | % | 1.5 | 1.6 | 1.6 | 1.3 | 1.0 |
| thermal expansion | | | | | | |
| Copper foil peeling | lb/in | 4.5 | 4.4 | 4.4 | 5.8 | 5.7 |
| strength | | | | | | |
| Water absorption | % | 0.26 | 0.26 | 0.26 | 0.25 | 0.25 |
| ratio | | | | | | |
| Shear viscosity | % | 47 | 50 | 50 | 35 | 27 |
| variation rate | | | | | | |

TABLE 8
Components (in parts by weight) and test results of the resin compositions
for Comparative Examples C8 to C11 and Examples E31to E32.

| Components | | C8 | C9 | C10 | E31 | C11 | E32 |
|---|---|---|---|---|---|---|---|
| Maleic anhydride- | Ricon 131MA5 | — | — | — | — | — | — |
| modified polyolefin | Ricon 130MA8 | 100 | 100 | 100 | 100 | 0 | — |
| | Ricon 130MA13 | — | — | — | — | — | — |
| | Ricon 131MA10 | — | — | — | — | — | — |
| | Ricon 156MA17 | — | — | — | — | — | — |
| | Ricon 184MA6 | — | — | — | — | — | — |
| | XIRAN-EF80 | — | — | — | — | — | — |
| Multifunctional | SR833S | 60 | 60 | 0 | 100 | 60 | 60 |
| (meth)acrylate | SR368NS | — | — | — | — | — | — |
| monomer and/or its | Oligomer of | — | — | — | — | — | — |
| oligomer | SR833S | | | | | | |
| | SR295 NS | — | — | — | — | — | — |
| | SR399 NS | — | — | — | — | — | — |
| | DPHA | — | — | — | — | — | — |
| Surface-porous | P1 | — | — | — | — | — | 20 |
| silica | P2 | — | — | — | — | — | — |
| | P3 | 0 | 40 | 20 | 20 | 20 | — |
| | P4 | — | — | — | — | — | — |
| Spherical SiO₂ | | 270 | 270 | 270 | 270 | 270 | 270 |
| (synthesis method) | | | | | | | |
| Nano silica | | — | — | — | — | — | — |
| Hollow silica | | — | — | — | — | — | — |
| Other resins | Ricon 130 | — | — | — | — | — | 100 |
| | G1726 | — | — | — | — | — | — |
| | SBS-A | — | — | — | — | — | — |
| | YD-128 | — | — | — | — | — | — |
| Initiator | DCP | 6.0 | 6.0 | 6.0 | 6.0 | 6.0 | 6.0 |
| Properties | Unit | C8 | C9 | C10 | E31 | C11 | E32 |
| Varnish storage life | Day(days) | >90 | >90 | 1-day | 25 | 20 | 35 |
| | | | | phase | | | |
| | | | | separation | | | |
| Organic volatile | % | 0.6 | 0.2 | 0.1 | 0.6 | 1.2 | 0.8 |
| matters | | | | | | | |
| Dissipation factor | / | 0.0036 | 0.0042 | 0.0036 | 0.0049 | 0.0061 | 0.0038 |
| Z-axis coefficient of | % | 1.4 | 1.1 | 2.5 | 1.1 | 1.0 | 1.3 |
| thermal expansion | | | | | | | |
| Copper foil peeling | lb/in | 3.8 | 4.6 | 3.5 | 4.9 | 3.6 | 3.1 |
| strength | | | | | | | |
| Water absorption | % | 0.27 | 0.24 | 0.20 | 0.38 | 0.50 | 0.26 |
| ratio | | | | | | | |
| Shear viscosity | % | 92 | 62 | 77 | 9 | 62 | 47 |
| variation rate | | | | | | | |

TABLE 9
Components (in parts by weight) and test results of the resin compositions
for Examples E33 to E34, and Comparative Examples C12 to C14.

| Components | | E33 | E34 | C12 | C13 | C14 |
|---|---|---|---|---|---|---|
| Maleic anhydride- | Ricon 131MA5 | — | — | — | — | — |
| modified polyolefin | Ricon 130MA8 | — | — | — | 100 | 100 |
| | Ricon 130MA13 | — | — | — | — | — |
| | Ricon 131MA10 | — | — | — | — | — |
| | Ricon 156MA17 | — | — | — | — | — |
| | Ricon 184MA6 | — | — | — | — | — |
| | XIRAN-EF80 | — | — | — | — | — |
| Multifunctional | SR833S | 60 | 60 | 60 | 60 | 60 |
| (meth)acrylate | SR368NS | — | — | — | — | — |
| monomer and/or its | Oligomer of | — | — | — | — | — |
| oligomer | SR833S | | | | | |
| | SR295 NS | — | — | — | — | — |
| | SR399 NS | — | — | — | — | — |
| | DPHA | — | — | — | — | — |
| Surface-porous | P1 | 20 | 20 | 20 | — | — |
| silica | P2 | — | — | — | — | — |
| | P3 | — | — | — | — | — |
| | P4 | — | — | — | — | — |
| Spherical SiO₂ | | 270 | 270 | 270 | 270 | 270 |
| (synthesis method) | | | | | | |
| Nano silica | | — | — | — | 20 | — |
| Hollow silica | | — | — | — | — | 20 |
| Other resins | Ricon 130 | — | — | — | — | — |
| | G1726 | 100 | — | — | — | — |
| | SBS-A | — | 100 | — | — | — |
| | YD-128 | — | — | 100 | — | — |
| Initiator | DCP | 6.0 | 6.0 | 6.0 | 6.0 | 6.0 |
| Properties | Unit | E33 | E34 | C12 | C13 | C14 |
| Varnish storage life | Day(days) | 1-day | 1-day | 15 | >90 | 60 |
| | | phase | phase | | | |
| | | separation | separation | | | |
| Organic volatile | % | 0.7 | 0.6 | 0.6 | 0.3 | 0.4 |
| matters | | | | | | |
| Dissipation factor | / | 0.0037 | 0.0038 | 0.0079 | 0.0043 | 0.0040 |
| Z-axis coefficient of | % | 2.0 | 1.9 | 1.3 | 1.3 | 1.4 |
| thermal expansion | | | | | | |
| Copper foil peeling | lb/in | 2.5 | 2.8 | 4.5 | 4.0 | 4.2 |
| strength | | | | | | |
| Water absorption | % | 0.25 | 0.25 | 0.52 | 0.26 | 0.27 |
| ratio | | | | | | |
| Shear viscosity | % | 53 | 56 | 71 | 95 | 94 |
| variation rate | | | | | | |

In the present disclosure, the properties tests of the examples and comparative examples are conducted by preparing the test specimens (samples) according to the following procedures and then performing tests according to the specific test conditions.

### 1. Varnish Containing Inorganic Filler

Each of the examples or comparative examples is prepared by adding the respective components, according to the amounts set forth in Tables 1 to 9, into a stirring tank, and stirring until completely dissolved and uniformly mixed at an environment of 25° C. to 80° C., thereby forming a resin composition containing inorganic filler, herein referred to as varnish containing inorganic filler.

### 2. Copper-Clad Resin Cured Product

A mold (for example, a completely cured laminate) is prepared, and a groove is formed on the mold, the varnish containing inorganic filler prepared from each of the examples or comparative examples is then placed into the groove, the copper foil (for example, 1 ounce HVLP copper foil) is applied on both the upper and lower surfaces, under high temperature, high pressure, and vacuum conditions, the assembly is pressed and cured (C-Stage) at a curing temperature between 200° C. and 210° C. for 120 to 150 minutes and at a pressing pressure between 400 psi and 500 psi. After the varnish is being completely cured, a numerically controlled molding machine (model TQZX-II) is used with a milling cutter of 1.6 mm diameter to mill the sample according to the shape of the groove, thereby obtaining a resin cured product with copper foil covering the upper and lower surfaces, herein referred to as the copper-clad resin cured product, for testing copper foil peeling strength.

### 3. Copper-Free Resin Cured Product

The above copper-clad resin cured product is subjected to etching to remove the copper foil on the upper and lower surfaces, thereby obtaining a copper-free resin cured product, for testing the dissipation factor, Z-axis percent of thermal expansion, and water absorption ratio.

The properties analysis items and test methods for the resin composition and the products thereof of the present disclosure are described as follows:

### 1. Varnish Shelf Life

The varnish without inorganic filler as described above is placed at 25° C., and each day the appearance of any brown solid precipitate is observed by the naked eye and the viscosity of the varnish is measured daily for 90 days, with the time at which precipitate appears or viscosity changes of greater than or equal to 10% being recorded. If no precipitate is observed and the viscosity change remains below 10% after 90 days, it is marked as >90, indicating a varnish shelf life greater than 90 days, for example, a varnish shelf life of 91 to 180 days, or 91 to 100 days, or 91 to 95 days. If at least one precipitate with a length of about 0.5 to 5 mm (usually brown) is formed, it is marked as “precipitate”, and observation is stopped and the number of days at which precipitation occurs is recorded. The occurrence of precipitate in the varnish will cause deterioration and variation in the subsequent properties of the resin cured product. If no precipitate is observed but the varnish viscosity changes by greater than or equal to 10%, observation is stopped and the number of days with a viscosity change of greater than or equal to 10% is recorded.

### 2. Percent of Organic Volatile Matters

The varnish containing inorganic filler described above is used as the sample to be tested. The sample is placed in a test aluminum plate, and by reference to IPC-TM-650 2.4.24.6 (2012), the sample is heated from 50° C. to 550° C. at a heating rate of 10° C./min, and the percentage of weight loss at 150° C. (in %) is recorded, representing the percent of organic volatile matters of the resin composition. The lower the percent of organic volatile matters, the more favorable the resin filling process and product yield.

### 3. Copper Foil Peeling Strength (or Peeling Strength, P/S)

The copper-clad resin cured product described above is cut into rectangular samples with a width of 24 mm and a length greater than 60 mm. The copper foil on the surface is etched, leaving a strip of copper foil with a width of 3.18 mm and a length greater than 60 mm. Using a universal tensile testing machine, the force required to peel the copper foil from the surface of the cured product is measured at room temperature (approximately 25° C.) by reference to IPC-TM-650 2.4.8 (2012), with the result expressed in lb/in.

### 4. Dissipation Factor (Df)

The copper-free resin cured productdescribed above is used as the sample to be tested. A microwave dielectrometer (available from AET, Japan) is employed by reference to JIS C2565 (1992) at room temperature (approximately 25° C.) and at a frequency of 10 GHz to measure each sample to be tested.

### 5. Z-Axis Percent of Thermal Expansion (Percent of Thermal Expansion, Z-PTE, in %)

The copper-free resin cured product described above is used as the sample to be tested. Thermal mechanical analysis (TMA) is conducted by reference to IPC-TM-650 2.4.24.5 (2012), by heating from 50° C. to 260° C. at a rate of 10° C. per minute, and the Z-axis thermal expansion (in %) of the sample to be tested in the temperature range of 50° C. to 260° C. is measured. When the measured value of the Z-axis thermal expansion of the resin cured product is less than or equal to 1.7%, a difference of greater than or equal to 0.1% between samples indicates a significant difference (since the resin cured product does not contain reinforcing materials, it is technically challenging to reduce the Z-axis thermal expansion).

### 6. Water Absorption Ratio

The copper-free resin cured product described above is used as the sample to be tested, by reference to IPC-TM-650 2.6.2.1 (2012), the sample is placed in an oven at 105±10° C. and baked for 1 hour, then removed and cooled at room temperature (approximately 25° C.) for 10 minutes, and weighed to obtain a weight of W₁. Subsequently, by reference to IPC-TM-650 2.6.16.1, the sample is subjected to a pressure cooking test (PCT) for 3 hours of moisture absorption (at 121° C. and 100% relative humidity), then removed, cooled, and the surface moisture is wiped off before weighing to obtain a weight of W₂. The water absorption ratio (%) is then calculated using the following formula:

$$Water absorption ratio ( \% ) = [ ( {W}_{2} - {W}_{1} ) / {W}_{1} ] \times 100 \% .$$

### 7. Shear Viscosity Variation Rate

The varnish containing inorganic filler described above is used as the sample to be tested, by reference to GB/T 2794-2022 7.3, a plate rheometer (model TA DHR-2) is used to test the varnish viscosity of the varnish containing inorganic filler at different shear rates. The test parameters are adjusted as follows: a cone (diameter 40 mm, angle 2°) is used on the upper part of the plate rheometer, with the bottom plate maintained at 25° C. The sample to be tested is placed on the bottom plate and kept at a constant temperature for 120 seconds prior to testing. During the test, the shear rate of the plate rheometer is set to range from 2.86 s⁻¹ to 57.30 s⁻¹ with an incremental change of 10 s⁻¹. After the test, a graph of varnish viscosity (in rad/s) versus shear rate (in s⁻¹) is obtained. The varnish viscosity at a shear rate of 2.86 s⁻¹ is recorded as N1, and at 28.6 s⁻¹ as N2. The varnish viscosity variation rate (%) is calculated as [(N1−N2)/N1]× 100%.

The varnish containing inorganic filler obtained from examples E1 to E10 and comparative examples C₁ to C₇ is used in the filling process of the printed circuit board, and the properties analysis items and test methods for the printed circuit board are described as follows:

### 1. Solder Floating Crack Rate

(1) Preparation of Copper-Clad Laminate with Plugged Holes

Two 3-ounce high-temperature high-elongation (HTE) copper foil and two prepregs obtained from 106 glass fiber fabric (for example, product EM-890, available from Elite Electronic Material (KunShan) Co., Ltd.) are prepared. They are stacked in the following order: one HVLP copper foil, two prepregs, and one HVLP copper foil. Under vacuum conditions, with a pressure of 500 psi at 210° C., the assembly is pressed for 2 hours to form a copper-clad inner laminate. Both sides of the copper-clad layer laminate are subjected to a brown treatment, followed by drilling. A hole plugging process is then performed in which the holes are filled with the varnish containing inorganic filler prepared from each of examples E1 to E10 or comparative examples C₁ to C₇, thereby obtaining a copper-clad layer laminate with plugged holes. The oven is then heated to 175° C., and the copper-clad inner layer laminate with plugged holes is placed in the oven and baked for 1 hour, then naturally cooled to 80° C., thereby obtaining a copper-clad laminate with plugged holes.

### (2) Preparation of Evaluation Laminate

Four prepregs obtained from 1078 L-glass fiber fabric (for example, product EM-890, available from Elite Electronic Material (KunShan) Co., Ltd.) and one copper-clad laminate with plugged holes as described above are prepared. They are alternately stacked in the order of two prepregs, one copper-clad laminate with plugged holes, and two prepregs. Then, one 18-μm thick HVLP copper foil is applied to both the top and bottom surfaces. Under vacuum conditions, with a pressure of 500 psi at 210° C., the assembly is pressed for 2 hours to form an evaluation laminate.

### (3) Determination of Solder Floating Crack Rate

The single-piece evaluation laminate described above is cut into 18 samples measuring 8 cm×10 cm. Each sample is placed in a solder bath at 288° C. for 10 seconds to perform solder floating, then removed and cooled for 120 seconds, and this cycle is repeated 20 times. The sample is then sliced at the drilled hole region and prepared for analysis. An optical microscope is used to observe whether cracks are present in the resin-filled area within each sample's holes. A crack is defined as a fracture occurring within the resin. For each single-piece evaluation laminate, the solder floating crack rate is calculated as (number of cracked holes×100%)/total number of holes. The lower the solder floating crack rate, the better, and a lower solder floating crack rate indicates stronger bonding force between the resin components and a higher hole plugging process yield.

### 2. Impedance Stability

A commercially available 20-layer HDI (High Density Interconnect) substrates with a designed characteristic impedance of 95 02 is selected. The holes in the High Density Interconnect substrates are filled with the varnish containing inorganic filler prepared from examples E1 to E10 or comparative examples C₁ to C₇, and the resin composition is heated to fully cure. A network analyzer equipped with a time-domain reflectometer (TDR) module (test parameters: 40 GHz, 25° C.) is used to measure the impedance between layer 2 and layer 19 of the HDI substrates to obtain an impedance curve. Since different materials are used in the hole regions and circuit regions, when the signal passes through the hole region, the impedance changes, causing the impedance curve to exhibit oscillations. The smaller the amplitude of the impedance in the hole region relative to that in the circuit region, the better the impedance stability, and thus the better the signal transmission performance of the printed circuit board. Here, A represents an amplitude of less than 5%, B represents an amplitude between 5% and 10%, and C represents an amplitude of greater than 10%.

### 3. Varnish Scraping Stability

The varnish containing inorganic filler produced from examples E1 to E10 or comparative examples C₁ to C₇ is used as the sample to be tested. A vacuum screen printing machine is used to perform scraping and filling of the holes, i.e., the varnish containing inorganic filler is filled into the holes. After starting the machine and adjusting the varnish scraping speed, the continuous varnish scraping causes the viscosity of the resin varnish to decrease, leading to insufficient resin in the filled holes. At this point, the machine must be stopped to adjust parameters, such as adjusting the varnish scraping speed or replacing the resin varnish. The longer the continuous varnish scraping time, the better the varnish scraping stability, indicating superior anti-thixotropic properties of the varnish. A represents a continuous varnish scraping time of greater than 1 h; B represents a continuous varnish scraping time between 15 min and 1 h; C represents a continuous varnish scraping time of less than 15 minutes.

Comprehensive reference to the results of property tests in Tables 1 to 9 clearly discloses the following phenomena:

The resin compositions of examples E1 to E10 exhibit an organic volatile matters of less than or equal to 2.0%, a shear viscosity variation rate of 9 to 56%, and a dissipation factor (Df) of less than or equal to 0.0080, whereas the resin compositions of comparative examples C₁ to C₇ do not meet one or more of the above properties. The printed circuit boards obtained from the resin compositions of examples E1 to E10 show significant improvements in impedance stability, solder floating crack rate, and varnish scraping stability compared to those obtained from the resin compositions of comparative examples C1 to C7.

A comparison of examples E11 to E30 with comparative examples C8 to C9 shows that, compared with the addition of 10 to 30 parts by weight of surface-porous silica (based on 100 parts by weight of maleic anhydride-modified polyolefin), when the amount of surface-porous silica is not within the range of 10 to 30 parts by weight, the products obtained from the resin composition exhibit a significant deterioration in the shear viscosity variation rate.

A comparison of examples E11 to E30 with comparative example C10 and example E31 shows that, compared with the addition of 30 to 90 parts by weight of multifunctional (meth)acrylate monomers and/or its oligomer (based on 100 parts by weight of maleic anhydride-modified polyolefin), when the amount of multifunctional (meth)acrylate monomers and/or its oligomer is not within the range of 30 to 90 parts by weight, the products obtained from the resin composition exhibit a significant deterioration in varnish shelf life.

A comparison of examples E11 to E30 with comparative example C₁₁ shows that, compared with the addition of 100 parts by weight of maleic anhydride-modified polyolefin, when no maleic anhydride-modified polyolefin is added in the resin composition, the products obtained from the resin composition exhibit a significant deterioration in varnish shelf life, organic volatile matters, dissipation factor, copper foil peeling strength, water absorption ratio, and shear viscosity variation rate.

In examples E11 to E30, using maleic anhydride-modified polyolefin, multifunctional (meth)acrylate monomers and/or its oligomer or a combination thereof, and surface-porous silica, compared with examples E32 to E34 (E32: adding polybutadiene Ricon 130, E33: adding hydrogenated styrene-butadiene-styrene block copolymer G1726, E34: adding styrene-butadiene-styrene triblock copolymer SBS-A) in which polyolefin other than maleic anhydride-modified polyolefin, multifunctional (meth)acrylate monomers and/or its oligomer or a combination thereof, and surface-porous silica are used, the products obtained from the resin composition have significantly improved varnish shelf life, organic volatile matters, and copper foil peeling strength.

In examples E11 to E30, using maleic anhydride-modified polyolefin, multifunctional (meth)acrylate monomers and/or its oligomer or a combination thereof, and surface-porous silica, compared with comparative example C₁₂ (C₁₂: adding bisphenol A-type epoxy resin YD-128) in which resin other than maleic anhydride-modified polyolefin, multifunctional (meth)acrylate monomers and/or its oligomer or a combination thereof, and surface-porous silica are used, the products obtained from the resin composition have significantly improved varnish shelf life, organic volatile matters, dissipation factor, water absorption ratio, and shear viscosity variation rate.

In examples E11 to E30, using maleic anhydride-modified polyolefin, multifunctional (meth)acrylate monomers and/or its oligomer or a combination thereof, and surface-porous silica, compared with comparative examples C13 to C14 (C13: adding nano silica YA050C-MJE; C14: adding hollow silica) in which other silica particles different from surface-porous silica, maleic anhydride-modified polyolefin, and multifunctional (meth)acrylate monomers and/or its oligomer are used, the products obtained from the resin composition have significantly improved at least the following property: shear viscosity variation rate.

What is claimed is:

1. A resin composition, characterized in that, the resin composition comprises the following components:
100 parts by weight of a thermosetting resin and 100 to 300 parts by weight of an inorganic filler;
the resin composition has an organic volatile matters as measured by reference to IPC-TM-650 2.4.24.6 of less than or equal to 2.0%,
the resin composition has a shear viscosity variation rate as measured by reference to GB/T 2794-2022 7.3 of 9 to 56%, and
a resin cured product obtained by curing the resin composition has a dissipation factor at a frequency of 10 GHz as measured by reference to JIS C2565 of less than or equal to 0.0080.

2. The resin composition according to claim 1, characterized in that, the resin composition has the organic volatile matters as measured by reference to IPC-TM-650 2.4.24.6 of less than or equal to 0.5%, and
the resin cured product obtained by curing the resin composition has the dissipation factor at a frequency of 10 GHz as measured by reference to JIS C2565 of less than or equal to 0.0041.

3. The resin composition according to claim 1, characterized in that, based on a total inorganic filler weight of 100 wt %, the inorganic filler comprises 50 to 100 wt % silica.

4. The resin composition according to claim 1, characterized in that, based on a total inorganic filler weight of 100 wt %, the inorganic filler comprises 2 to 17 wt % surface-porous silica.

5. The resin composition according to claim 4, characterized in that, a specific surface area of the surface-porous silica is 40 to 200 m²/g.

6. The resin composition according to claim 4, characterized in that, a specific surface area of the surface-porous silica is 103 to 200 m²/g.

7. The resin composition according to claim 1, characterized in that, the thermosetting resin comprises any one of a polyolefin, an acrylate ester compound, a maleimide resin, an organic silicone resin, a polyphenylene ether resin, a benzoxazine resin, an epoxy resin, an active ester, a phenol resin, and a cyanate ester resin, or a combination thereof.

8. The resin composition according to claim 1, characterized in that, the resin composition does not comprise an organic solvent.

9. The resin composition according to claim 1, characterized in that, the thermosetting resin comprises (A) a maleic anhydride-modified polyolefin and (B) a multifunctional (meth)acrylate monomer and/or its oligomer; and
the inorganic filler comprises (C) a surface-porous silica and (D) a non-porous silica.

10. The resin composition according to claim 9, characterized in that, a weight ratio of (A) the maleic anhydride-modified polyolefin:(B) the multifunctional (meth)acrylate monomer and/or itsoligomer:(C) the surface-porous silica:(D) the non-porous silica is 100:(30 to 90):(10 to 30):(150 to 350).

11. The resin composition according to claim 9, characterized in that, a weight ratio of (C) the surface-porous silica to (D) the non-porous silica is from (1:5) to (1:35).

12. The resin composition according to claim 1, characterized in that, the resin composition further comprises at least one of a flame retardant, a curing accelerator, a polymerization inhibitor, a coloring agent, a surfactant, and a toughening agent, or a combination thereof.

13. An article manufactured from the resin composition according to claim 1, characterized in that, the article comprises a prepreg, a resin film, a laminate, or a printed circuit board.

14. An article made from the resin composition according to claim 1, characterized in that, the article comprises a resin cured product obtained by curing the resin composition.

15. A printed circuit board produced by employing the resin composition according to claim 1 in a resin filling process of a printed circuit board, characterized in that, the printed circuit board has one or more of the following properties:
a solder floating crack rate in a resin cured product area of printed circuit boards as measured by reference to IPC-TM-650 2.4.13.1 of 0%;
an impedance amplitude in a resin cured product area of printed circuit boards as measured by a network analyzer of less than or equal to 10%; and
a continuous varnish scraping time of greater than or equal to 15 minutes during the resin filling process of the printed circuit board.

16. A use of the resin composition according to claim 1 applied in a resin filling process of a printed circuit board.

17. The use according to claim 16, characterized in that, the resin filling process of the printed circuit board comprises one or more of a hole plugging process of a printed circuit board, a groove filling process of a printed circuit board, or a circuit filling process of a printed circuit board.

18. The use according to claim 17, characterized in that, in the hole plugging process of the printed circuit board, at least one hole of the printed circuit board is filled with a resin cured product of the resin composition; and/or
in the groove filling process of the printed circuit board, at least one groove of the printed circuit board is filled with a resin cured product of the resin composition; and/or
in the circuit filling process of the printed circuit board, at least one circuit open area of the printed circuit board is covered with a resin cured product of the resin composition.
